(19) United States
(12) Patent Application Publication
(10) Pub. No.: US 2026/0329358 A1
(43) Pub. Date: Oct. 22, 2026

(54) Cooperative Power Supply System

(71) Applicant: Hiroshi Iwasa, Tokyo (JP)

(72) Inventor: Hiroshi Iwasa, Nishi-Tokyo (JP)

(21) Appl. No.: 19/347,853

(22) Filed: Oct. 2, 2025

(30) Foreign Application Priority Data
Apr. 16, 2025 (JP) 2025-067788

(51) Int. Cl. G06F 1/26; G06F 1/32; H02J 4/25; H02J 101/24; H02M 1/088; H03K 17/06; H03K 17/284; H03K 19/20

(52) U.S. Cl. CPC G06F 1/263; G06F 1/32; H02J 4/25; H02M 1/088; H03K 17/063; H03K 17/284; H03K 19/20; H02J 2101/25

(57) ABSTRACT

By using feedback control for coordinated power supply, the power from the solar modules is supplied preferentially, and only the shortfall is supplied from the computer (PC). By adjusting the wiring inside the computer (PC), the power from the solar modules is converted only once, and additional voltage conversion is not performed in the power supply for computer (PC). Furthermore, in coordinated power supply, the front stage is divided into two systems to ensure sufficient static margin, and the rear stage is made into an nMOS inverter circuit or the like to ensure sufficient dynamic margin. The static margin and dynamic margin enable stable operation. Furthermore, a delay circuit allows it to be linked to the power interface of the computer (PC).

The present invention relates to a DC power supply system that uses natural energy. In particular, it relates to a DC power supply system that stably supplies power to precision equipment such as PCs (computers, personal computers).

### CROSS-REFERENCE TO RELATED APPLICATION

The present application claims the benefit application number 2025-067788, filed in Japan on Apr. 16, 2025, the subject matter of which is hereby incorporated herein by reference.

### STATEMENT REGARDING FEDERALLY SPONSORED RESEARCH OR DEVELOPMENT

The inventor is not sponsored by federal government.

[Reference to a “Sequence Listing,” a table, or a computer program listing appendix submitted on a compact disc and an incorporation-by-reference of the material on the compact disc]
N/A

### BACKGROUND OF THE INVENTION

In today's world, most electronic devices operate on DC, but since the power supplied is AC, most electronic devices use AC power converted to DC. Usually, to convert AC power to DC, power supplies for PCs (computers) and AC (Altemative Current) adapters that use AC-DC converters are used.

In recent years, natural energy such as solar modules has also become widespread. Power generated by solar modules is DC in its original state. Since the power supplied by the power company is AC, it is inevitable that power supplies for PCs (computers) or AC (Alternative Current) adapters that use AC-DC converters are used. However, nowadays, it is common to convert the power generated by solar modules, which is DC, into AC using a power conditioner, and then convert it back to DC using a personal computer power supply or AC adapter.

The efficiency of converting the DC generated by solar modules into AC is, for example, about 80%. The efficiency of converting it back to DC is also about 80%. Therefore, only 64% of the power generated by solar modules can actually be used by electronic devices. 36% of the power generated by solar modules is lost in the conversion process and is not used effectively.

Therefore, Patent Document 1 and other documents describe a method in which power generated by natural energy sources such as solar modules is used as DC without first converting it to AC.

[Patent Document 1] JP2013-90560

In this method, it is described that the power generated by natural energy such as solar modules is used as DC and given priority, and power is supplied from an AC power source when the shortage is taken into consideration.

### BRIEF SUMMARY OF THE INVENTION

### Problem to be Solved by the Invention

In this method, no effort is made to stably operate electronic devices with DC power. When used as a power source such as 12V (volts) used inside a computer (PC), there is a problem as to whether it will operate stably. Will it operate stably with the method of Patent Document 1? It will probably operate stably.

The reason for this is that a storage battery, an electric double layer capacitor, or a storage battery+electric double layer capacitor is connected to the DC part. It is thought that the method of Patent Document 1 operates stably thanks to such a storage device.

So, are such storage devices necessary? Normally, even in a DC power supply system using small-scale natural energy, the storage battery costs more than tens of thousands of yen and reaches the end of its life in a few years. Storage batteries have a relatively short lifespan, and depreciation costs are often somewhat high. Electric double-layer capacitors have a relatively long lifespan, but are relatively expensive to ensure sufficient capacity. For this reason, it would be better to realize a DC power supply system that uses natural energy and can operate without a large-capacity storage device.

Therefore, the object of the present invention is to provide a DC power supply system that can efficiently use DC power from solar modules and stably supply a power source such as 12V (volts) that can be used inside a computer (PC) without a large-capacity storage device such as a storage battery or electric double-layer capacitor.

The power supply device comprise
a first node, a second node, a third node, a fourth node;
a first DC-DC converter;
a first switching element or a group of first switching elements;
a second switching element or a group of second switching elements;
wherein the potential of the first node is output to the second node via the first DC-DC converter;
the first switching element or group thereof is connected between the second node and the fourth node;
the second switching element or group thereof is connected between the third node and the fourth node;
the first switching element or group thereof has a fully-off state, a fully-on state, and an intermediate state between on and off, and transitions analogously between on and off based on the voltage applied to its control terminal;
the second switching element or group thereof has a fully-off state, a fully-on state, and an intermediate state between on and off, and transitions analogously between on and off based on the voltage applied to its control terminal;
when the potential of the first node is equal to or less than a first predetermined potential value, the first switching element or group thereof is fully turned off, and the second switching element or group thereof is fully turned on;
when the potential of the first node is equal to or greater than a third predetermined potential value and equal to or less than a fourth predetermined potential value, both the first and second switching elements or groups thereof are fully turned on;
when the potential of the first node is equal to or greater than a second predetermined potential value, the first switching element or group thereof is fully turned on, and the second switching element or group thereof is fully turned off;
wherein the third predetermined potential value is greater than the first predetermined potential value, the fourth predetermined potential value is greater than the third predetermined potential value, and the second predetermined potential value is greater than the fourth predetermined potential value;
when the potential of the first node rapidly drops from a value exceeding the second predetermined potential value to a value below the first predetermined potential value, the first switching element or group thereof starts in an on state and the second switching element or group thereof starts in an off state, then both become on, and subsequently the first switching element or group thereof becomes off while the second switching element or group thereof remains on;
when the potential of the first node rapidly rises from a value below the first predetermined potential value to a value exceeding the second predetermined potential value, the first switching element or group thereof starts in an off state and the second switching element or group thereof starts in an on state, then both become on, and subsequently the first switching element or group thereof remains on while the second switching element or group thereof becomes off.

The DC power supply system of the present invention can efficiently utilize power, especially DC power from solar modules, and can stably supply a power source such as 12V (volts) that can be used inside a computer (PC). In addition, since only the computer (PC) part needs to be modified and there is no need to modify the power system of the commercial power source (100V, etc.) of the entire house or building, the threshold for introduction is low.

### BRIEF DESCRIPTION OF THE SEVERAL VIEWS OF THE DRAWING

FIG. 1 is a block diagram of a first embodiment of the present invention.

FIG. 2 is a circuit diagram of a coordinated power supply circuit of a first embodiment of the present invention.

FIG. 3 is an example of a circuit diagram of a DC-DC converter.

FIG. 4 is an example of a circuit diagram inside a power supply for a computer (PC).

FIG. 5 is an example of a circuit diagram of an inverter.

FIG. 6 is a circuit diagram showing a basic coordinated power supply.

FIG. 7 is a current graph showing coordinated power supply.

FIG. 8 is a voltage-current characteristic and a voltage-power characteristic of a solar module.

FIG. 9 is a simplified circuit diagram showing coordinated power supply.

FIG. 10 is a circuit used to compare inverters and the results of the simulation (circuit A).

FIG. 11 is a circuit used to compare inverters and the results of the simulation (circuit I).

FIG. 12 is a circuit used to compare inverters and the results of the simulation (circuit U).

FIG. 13 is a circuit used to compare inverters and the results of the simulation (circuit E).

FIG. 14 is a circuit used to compare inverters and the results of the simulation (circuit O).

FIG. 15 is a circuit used to compare inverters and the results of the simulation (circuit Ka).

FIG. 16 is an explanatory diagram of cases where a reverse current prevention diode is and is not required.

FIG. 17 is a circuit diagram of the part that is linked to the power button of a computer (PC).

FIG. 18 is the pin assignment of the CPU power connector.

FIG. 19 is the pin assignment of the storage power connector.

FIG. 20 is the pin assignment of a motherboard power connector.

FIG. 21 is the pin assignment of a graphics board power connector.

FIG. 22 is a diagram showing the relationship between the power connector and the circuitry of the present invention.

FIG. 23 is a second block diagram of the present invention.

### DETAILED DESCRIPTION OF THE INVENTION

The first embodiment relates to a coordinated power supply system. First, the circuit connections are explained, and then the operation is explained. After that, each related technology and each element technology is explained.

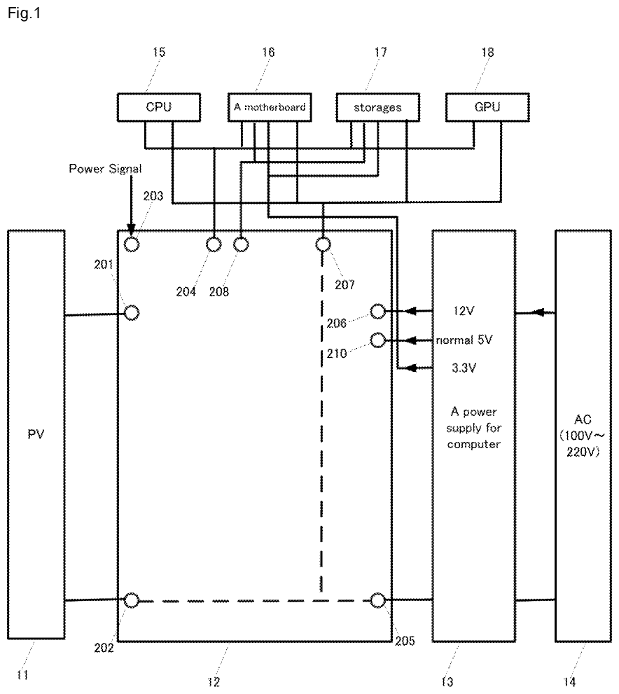

First, the circuit connections are explained. FIG. 1 is a block diagram of the first embodiment of the [symbol] this invention. The DC power supply system of the first embodiment is composed of a solar module 11, a main circuit 12, a power supply 13 for a computer (PC), a commercial power supply 14, a CPU 15, a motherboard 16, a storage 17, and a GPU 18.

The positive side of the solar module 11 is connected to the main circuit 12 via a terminal 201. The negative side of the solar module 11 is connected to the main circuit 12 via a terminal 202.

The positive side of the commercial power supply 14 is connected to the power supply 13 for a computer (PC). The negative side of the commercial power supply 14 is connected to the power supply 13 for a computer (PC). The normal 12V output of the power supply for computer (PC) is connected to the main circuit 12 via terminal 206. The normal 5V output of the power supply for computer (PC) is connected to the main circuit 12 via terminal 210. The normal 3.3V output of the power supply for computer (PC) is connected to the motherboard 16 and storage 17. The GND of the power supply for computer (PC) is connected to the main circuit 12 via terminal 205.

The normal 12V output of the main circuit 12 is connected to the CPU 15, motherboard 16, storage 17, and GPU 18 via terminal 204. The normal 5V output of the main circuit 12 is connected to the motherboard 16 and storage 17 via terminal 208. The GND of the main circuit 12 is connected to the CPU 15, motherboard 16, storage 17, and GPU 18 via terminal 207.

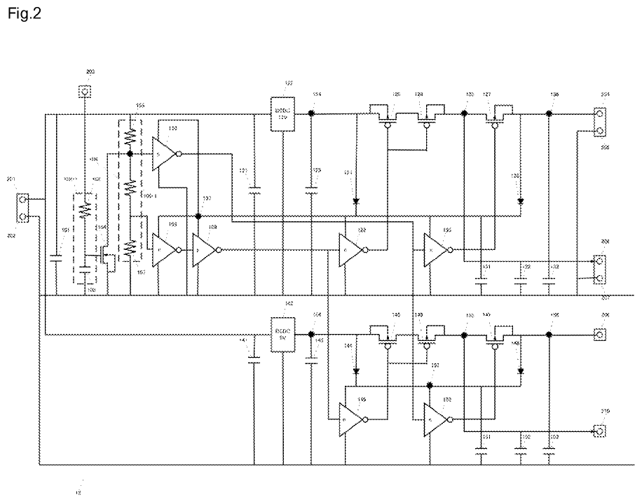

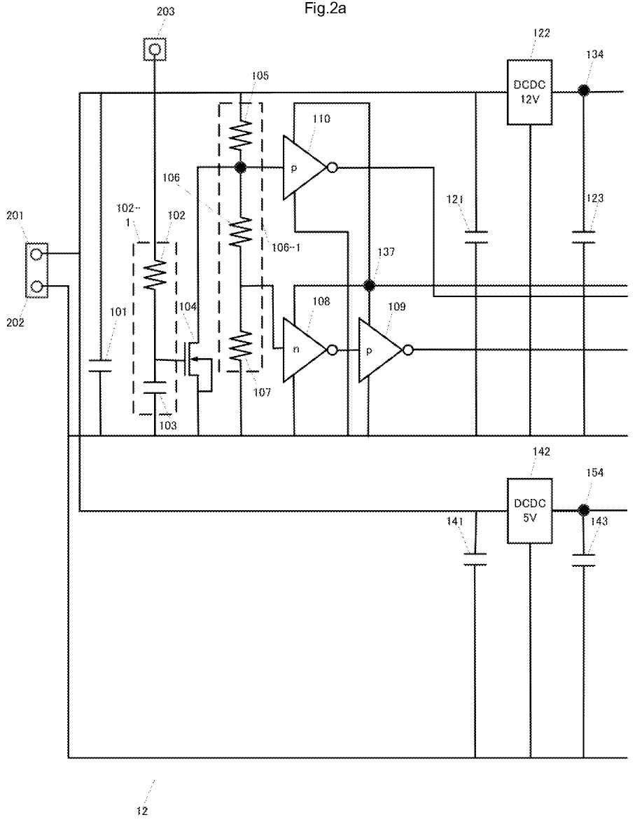

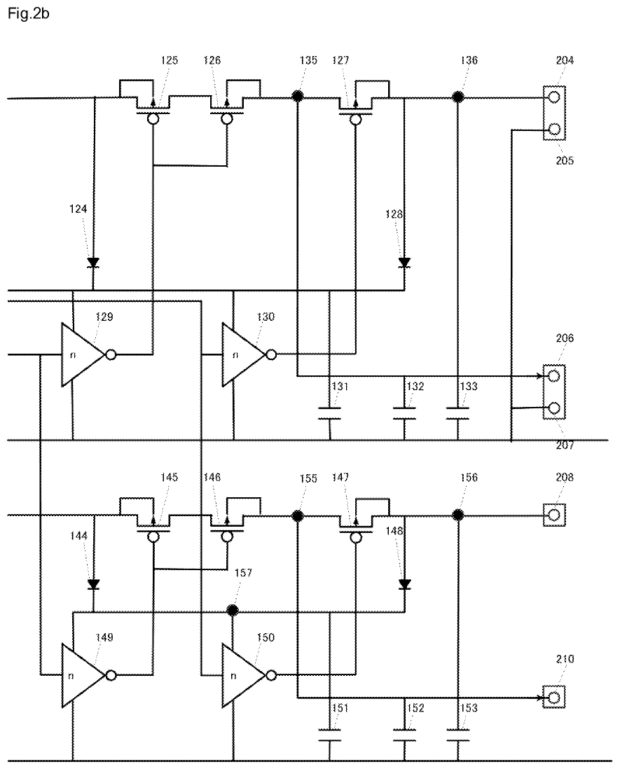

FIG. 2 is a circuit diagram of the main circuit 12. The main circuit 12 includes terminals 201, 202, 203, 204, 205, 206, 207, 208, a terminal block 210, a capacitor 101, a resistor 102, a capacitor 103, an nMOS field effect transistor 104, a resistor 105, a resistor 106, a resistor 107, an nMOS inverter 108, a pMOS inverter 109, a pMOS inverter 110, a capacitor 121, a DC-DC converter 122, a capacitor 123, a diode 124, a pMOS field effect transistor 125, a pMOS field effect transistor 126, a It is composed of transistor 126, diode 128, nMOS inverter 129, nMOS inverter 130, capacitor 131, capacitor 132, capacitor 133, capacitor 141, DC-DC converter 142, capacitor 143, diode 144, pMOS field effect transistor 145, pMOS field effect transistor 146, pMOS field effect transistor 147, diode 148, nMOS inverter 149, nMOS inverter 150, capacitor 151, capacitor 152, and capacitor 153.

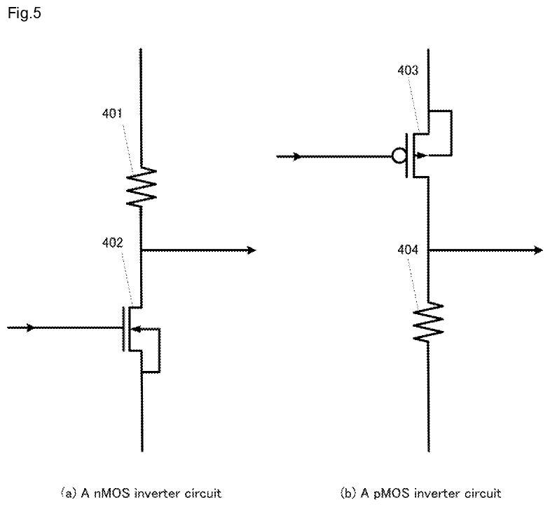

The contents of nMOS inverter 108, pMOS inverter 109, pMOS inverter 110, nMOS inverter 129, nMOS inverter 130, nMOS inverter 149, and nMOS inverter 150 will be explained with reference to FIG. 5. The contents of nMOS inverter 108 are as shown in FIG. 5(a). The contents of pMOS inverter 109 are as shown in FIG. 5(b). The contents of the pMOS inverter 110 are as shown in FIG. 5(b). The contents of the nMOS inverter 129 are as shown in FIG. 5(a). The contents of the nMOS inverter 130 are as shown in FIG. 5(a). The contents of the nMOS inverter 149 are as shown in FIG. 5(a). The contents of the nMOS inverter 150 are as shown in FIG. 5(a).

Terminal 201 is connected to the positive side of capacitor 101, one end of resistor 105, the input of DC/DC converter 122, the positive side of capacitor 141, and the input of DC/DC converter 142. Terminal 202 is GND and is connected to many elements, but is omitted because there are many connections. Terminal 203 is connected to one end of resistor 102. Terminal 204 is connected to the source of pMOS field effect transistor 127, the anode of diode 128, and the positive side of capacitor 133. Terminal 205 is GND and is connected to many elements, but is omitted because there are many connections. Terminal 206 is connected to the source of pMOS field effect transistor 126, the drain of pMOS field effect transistor 127, and the positive side of capacitor 132. Terminal 207 is GND and is connected to many elements, but is omitted because there are many connections. Terminal 208 is connected to the source of pMOS field effect transistor 147, the anode of diode 148, and the positive side of capacitor 153. Terminal 210 is connected to the source of pMOS field effect transistor 146, the drain of pMOS field effect transistor 147, and the positive side of capacitor 152.

The positive side of capacitor 101 is connected to terminal 201, one end of resistor 102, one end of resistor 105, the positive side of capacitor 121, the input of DC-DC converter 122, the positive side of capacitor 141, and the input of DC-DC converter 142.

Delay circuit 102-1 is composed of resistor 102 and capacitor 103. One end of resistor 102 is connected to terminal 201, one end of resistor 105, the positive side of capacitor 121, the input of DC-DC converter 122, the positive side of capacitor 141, and the input of DC-DC converter 142. The other end of the resistor 102 is connected to the positive side of the capacitor 103 and the gate of the nMOS field effect transistor 104. The positive side of the capacitor 103 is connected to one end of the resistor 102 and the gate of the nMOS field effect transistor 104. The negative terminal of the capacitor 103 is connected to GND. The source of the field effect transistor 104 is connected to GND. The gate of the field effect transistor 104 is connected to one end of the resistor 102 and the positive side of the capacitor 103. The drain of the field effect transistor 104 is connected to one end of the resistor 105, one end of the resistor 106, and the input of the pMOS inverter 110.

The resistive voltage divider 106-1 is composed of resistors 105, 106, and 107. One end of the resistor 105 is connected to the terminal 201, the positive side of the capacitor 101, the input of the DC-DC converter 122, the positive side of the capacitor 141, and the input of the DC-DC converter 142. The other end of resistor 105 is connected to the source of nMOS field effect transistor 104, one end of resistor 106, and the input of pMOS inverter 110. One end of resistor 106 is connected to the drain of nMOS field effect transistor 104, one end of resistor 105, and the input of pMOS inverter 110. The other end of resistor 106 is connected to one end of resistor 107 and the input of nMOS inverter 108. One end of resistor 107 is connected to one end of resistor 106 and the input of nMOS inverter 108.

The other end of resistor 107 is connected to GND.

The input of nMOS inverter 108 is connected to resistor 106 and resistor 107. The output of nMOS inverter 108 is connected to the input of pMOS inverter 109. The VDD terminal of the nMOS inverter 108 is connected to the cathode of the diode 124, the cathode of the diode 128, the VDD terminal of the pMOS inverter 109, the VDD terminal of the pMOS inverter 110, the VDD terminal of the pMOS inverter 109, the VDD terminal of the nMOS inverter 129, the VDD terminal of the nMOS inverter 130, and the positive terminal of the capacitor 131. The VSS of the nMOS field effect transistor 108 is connected to GND.

The input of the pMOS inverter 109 is connected to the output of the nMOS inverter 108. The output of the pMOS inverter 109 is connected to the input of the nMOS inverter 129 and the input of the nMOS inverter 149. The VDD terminal of the pMOS inverter 109 is connected to the cathode of the diode 124, the cathode of the diode 128, the VDD terminal of the nMOS inverter 108, the VDD terminal of the pMOS inverter 110, the VDD terminal of the pMOS inverter 109, the VDD terminal of the nMOS inverter 129, the VDD terminal of the nMOS inverter 130, and the positive terminal of the capacitor 131. The VSS of the pMOS inverter 109 is connected to GND.

The input of the pMOS inverter 110 is connected to one end of the resistor 105 and one end of the resistor 106 and drain of nMOS field effect transistor 104. The output of the pMOS inverter 110 is connected to the input of the nMOS inverter 130 and the input of the nMOS inverter 150. The VDD terminal of the pMOS inverter 110 is connected to the cathode of the diode 124, the cathode of the diode 128, the VDD terminal of the nMOS inverter 108, the VDD terminal of the pMOS inverter 109, the VDD terminal of the nMOS inverter 129, the VDD terminal of inverter 130, and the positive terminal of the capacitor 131. The VSS of the pMOS inverter 110 is connected to GND.

The input of the nMOS inverter 129 is connected to the output of the pMOS inverter 109 and the input of the nMOS inverter 149. The output of the nMOS inverter 129 is connected to the gate of the pMOS field effect transistor 125 and the gate of the pMOS field effect transistor 126. The VDD terminal of the nMOS inverter 129 is connected to the cathode of the diode 124, the cathode of the diode 128, the VDD terminal of the nMOS inverter 108, the VDD terminal of the pMOS inverter 109, the VDD terminal of the pMOS inverter 110, the VDD terminal of the nMOS inverter 130, and the positive terminal of the capacitor 131. The VSS of the nMOS inverter 129 is connected to GND.

The input of the nMOS inverter 130 is connected to the output of the pMOS inverter 110 and the input of the nMOS inverter 150. The output of the nMOS inverter 130 is connected to the gate of the pMOS inverter 127. The VDD terminal of the nMOS inverter 130 is connected to the cathode of the diode 124, the cathode of the diode 128, the VDD terminal of the nMOS inverter 108, the VDD terminal of the pMOS inverter 109, the VDD terminal of the pMOS inverter 110, the VDD terminal of the nMOS inverter 129, and the positive terminal of the capacitor 131. The VSS of the nMOS inverter 130 is connected to GND.

The input of the DC-DC converter 122 is connected to the terminal 201, the positive side of the capacitor 101, one end of the resistor 105, the positive side of the capacitor 121, the positive side of the capacitor 141, and the input of the DC-DC converter 142. The output of the DC-DC converter 122 is connected to the positive terminal of the capacitor 123, the anode of the diode 124, and the source of the pMOS field effect transistor 125. The GND terminal of the DC-DC converter 122 is connected to GND.

The positive terminal of capacitor 121 is connected to the input of DC-DC converter 122, terminal 201, the positive side of capacitor 101, one end of resistor 105, the positive side of capacitor 141, and the input of DC-DC converter 142. The negative terminal of capacitor 121 is connected to GND.

The positive terminal of capacitor 123 is connected to the output of DC-DC converter 122, the anode of diode 124, and the source of pMOS field effect transistor 125. The negative terminal of capacitor 123 is connected to GND.

The anode of diode 124 is connected to the output of DC-DC converter 122, the anode of capacitor 123, and the source of pMOS field effect transistor 125. The cathode of the diode 124 is connected to the VDD terminal of the nMOS inverter 108, the VDD terminal of the pMOS inverter 109, the VDD terminal of the pMOS inverter 110, the VDD terminal of the nMOS inverter 129, and the VDD terminal of the nMOS inverter 130.

The source of the pMOS field effect transistor 125 is connected to the output of the DC-DC converter 122, the positive terminal of the capacitor 123, and the anode of the diode 124. The gate of the pMOS field effect transistor 125 is connected to the gate of the pMOS field effect transistor 126, and the output of the nMOS inverter 129. The drain of the pMOS field effect transistor 125 is connected to the drain of the pMOS field effect transistor 126.

The source of the pMOS field effect transistor 126 is connected to the drain of the pMOS field effect transistor 127, the positive terminal of the capacitor 132, and the terminal 206. The gate of the pMOS field effect transistor 126 is connected to the gate of the pMOS field effect transistor 125 and the output of the nMOS inverter 129. The drain of the pMOS field effect transistor 126 is connected to the drain of the pMOS field effect transistor 125.

The source of the pMOS field effect transistor 127 is connected to the terminal 204, the anode of the diode 128, and the positive terminal of the capacitor 133. The gate of the pMOS field effect transistor 127 is connected to the output of the nMOS field effect transistor 130. The drain of the pMOS field effect transistor 127 is connected to the source of the pMOS field effect transistor 126, the positive terminal of the capacitor 132, and the terminal 206.

The anode of the diode 128 is connected to the terminal 204 and the source of the nMOS field effect transistor 127. The cathode of diode 128 is connected to the cathode of diode 124, the VDD terminal of nMOS inverter 108, the VDD terminal of pMOS inverter 109, the VDD terminal of pMOS inverter 110, the VDD terminal of nMOS inverter 129, the VDD terminal of nMOS inverter 130, and the positive terminal of capacitor 131.

The positive terminal of capacitor 131 is connected to the cathode of diode 128, the cathode of diode 124, the VDD terminal of nMOS inverter 108, the VDD terminal of pMOS inverter 109, the VDD terminal of pMOS inverter 110, the VDD terminal of nMOS inverter 129, and the VDD terminal of nMOS inverter 130. The negative terminal of capacitor 131 is connected to GND.

The positive terminal of capacitor 132 is connected to the source of pMOS field effect transistor 126, the drain of pMOS field effect transistor 127, and terminal 206. The negative terminal of capacitor 132 is connected to GND.

The positive terminal of capacitor 133 is connected to the source of pMOS field effect transistor 127 and terminal 204. The negative terminal of capacitor 133 is connected to GND.

The source of terminal 204 is connected to the source of pMOS field effect transistor 127, the anode of diode 128, and the positive terminal of capacitor 133. Terminal 205 is connected to GND. Terminal 206 is connected to the source of pMOS field effect transistor 126, the drain of pMOS field effect transistor 127, and the positive terminal of capacitor 132. Terminal 207 is connected to GND.

The positive terminal of capacitor 141 is connected to the positive terminal of capacitor 121, the input of DC-DC converter 122, terminal 201, the positive side of capacitor 101, one end of resistor 105, and the input of DC-DC converter 142. The negative terminal of capacitor 141 is connected to GND.

The input of DC-DC converter 142 is connected to the positive terminal of capacitor 121, the input of DC-DC converter 122, terminal 201, the positive side of capacitor 101, one end of resistor 105, and the positive terminal of capacitor 141. The output of DC-DC converter 142 is connected to the positive side of capacitor 143, the anode of diode 144, and the source of pMOS field effect transistor 145. The GND of DC-DC converter 142 is connected to GND.

The positive terminal of capacitor 143 is connected to the output of DC-DC converter 142, the anode of diode 144, and the source of pMOS field effect transistor 145. The negative terminal of capacitor 143 is connected to GND.

The anode of diode 144 is connected to the output of DC-DC converter 142, the positive terminal of capacitor 143, and the source of pMOS field effect transistor 145. The cathode of the diode 144 is connected to the cathode of the diode 148, the positive terminal of the nMOS inverter 149, and the positive terminal of the nMOS inverter 150.

The source of the pMOS field effect transistor 145 is connected to the output of the DC-DC converter 142, the positive terminal of the capacitor 143, and the anode of the diode 144. The gate of the pMOS field effect transistor 145 is connected to the gate of the pMOS field effect transistor 146, and the output of the nMOS inverter 149. The drain of the pMOS field effect transistor 145 is connected to the drain of the pMOS field effect transistor 146. The source of the pMOS field effect transistor 146 is connected to the drain of the pMOS field effect transistor 147, the positive side of the capacitor 152, and the terminal 210. The gate of the pMOS field effect transistor 146 is connected to the gate of the pMOS field effect transistor 145, and the output of the nMOS inverter 149. The drain of the pMOS field effect transistor 146 is connected to the drain of the pMOS field effect transistor 145.

The source of the pMOS field effect transistor 147 is connected to the anode of the diode 148, the positive terminal of the capacitor 153, and the terminal 208. The gate of the pMOS field effect transistor 147 is connected to the output of the nMOS inverter 150. The drain of the pMOS field effect transistor 147 is connected to the source of the pMOS field effect transistor 146, the positive side of the capacitor 152, and the terminal 210.

The anode of the diode 148 is connected to the source of the pMOS field effect transistor 147, the positive side of the capacitor 153, and the terminal 208. The cathode of the diode 148 is connected to the cathode of the diode 144, the VDD of the nMOS inverter 149, and the VDD of the nMOS inverter 150.

The input of the nMOS inverter 149 is connected to the output of the pMOS inverter 109 and the input of the nMOS inverter 129. The output of the nMOS inverter 149 is connected to the gate of the pMOS field effect transistor 145 and the gate of the pMOS field effect transistor 146. The VDD of the nMOS inverter 149 is connected to the cathode of the diode 144, the cathode of the diode 148, the VDD of the nMOS inverter 150, and the positive side of the capacitor 151. The VSS of the nMOS inverter 149 is connected to GND.

The input of the nMOS inverter 150 is connected to the output of the pMOS inverter 110 and the input of the nMOS inverter 130. The output of the nMOS inverter 150 is connected to the gate of the pMOS field effect transistor 147. VDD of the nMOS inverter 150 is connected to the cathode of the diode 144, the cathode of the diode 148, VDD of the nMOS inverter 149, and the positive side of the capacitor 151. VSS of the nMOS inverter 150 is connected to GND.

The positive terminal of the capacitor 151 is connected to the cathode of the diode 144, the cathode of the diode 148, the VDD of the nMOS inverter 149, and the VDD of the nMOS inverter 150. The negative terminal of the capacitor 151 is connected to GND.

The positive side of the capacitor 152 is connected to the source of the pMOS field effect transistor 146, the drain of the pMOS field effect transistor 147, and the terminal 210. The negative terminal of the capacitor 152 is connected to GND.

The positive terminal of the capacitor 153 is connected to the source of the pMOS field effect transistor 147, the anode of the diode 148, and the terminal 208. The negative terminal of the capacitor 153 is connected to GND.

The terminal 208 is connected to the source of the pMOS field effect transistor 147, the anode of the diode 148, and the positive terminal of the capacitor 153. Terminal 210 is connected to the source of field effect transistor 146, the drain of field effect transistor 147, and the positive terminal of capacitor 152.

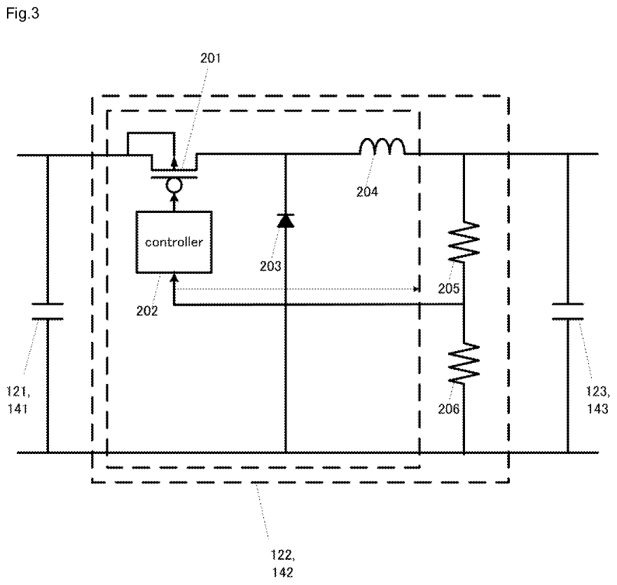

FIG. 3 shows an example of the internal circuit of DC-DC converters 122 and 142. DC-DC converters 122 and 142 are composed of pMOS field effect transistor 201, controller 202, diode 203, inductor 204, resistor 205, and resistor 206. Capacitors 121 and 141 and capacitors 123 and 143 are the same as those described in FIG. 2, but are also shown in FIG. 3 because they are important for the operation of the DC-DC converter.

The positive terminal of capacitor 121 is connected to the source of pMOS field effect transistor 201. The negative terminal of capacitor 121 is connected to GND.

The source of pMOS field effect transistor 201 is connected to the positive terminal of capacitor 121. The gate of the pMOS field effect transistor 201 is connected to the output of the controller 202. The drain of the pMOS field effect transistor 201 is connected to the cathode of the diode 203 and one end of the inductor 204.

The anode of the diode 203 is connected to GND. The cathode of the diode 203 is connected to the drain of the pMOS field effect transistor 201 and one end of the inductor 204.

One end of the inductor 204 is connected to the drain of the pMOS field effect transistor 201 and the cathode of the diode 203. The other end of the inductor 204 is connected to one end of the resistor 205 and the positive sides of the capacitors 123 and 143.

One end of the resistor 205 is connected to one end of the inductor 204 and the positive sides of the capacitors 123 and 143. The other end of the resistor 205 is connected to one end of the resistor 206 and the input of the controller 202.

One end of resistor 206 is connected to one end of resistor 205 and the input of controller 202. The other end of resistor 206 is connected to GND.

The positive sides of capacitors 123 and 143 are connected to one end of inductor 204 and one end of resistor 205. The negative sides of capacitors 123 and 143 are connected to GND.

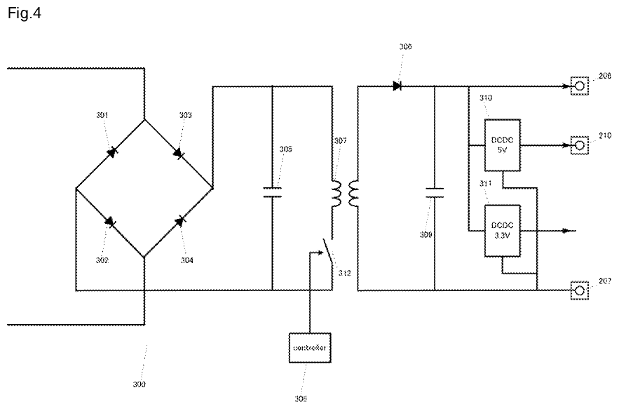

FIG. 4 shows an example of the internal configuration of a computer (PC) power supply. A computer (PC) power supply 300 is composed of terminals 206, 210, and 207, diode 301, diode 302, diode 303, diode 304, capacitor 305, diode 306, transformer 307, controller 308, capacitor 309, DC-DC converter 310, and DC-DC converter 311.

The anode of diode 301 is connected to the anode of diode 302. The cathode of diode 301 is connected to the anode of diode 303.

The anode of diode 302 is connected to the anode of diode 301. The cathode of diode 302 is connected to the anode of diode 304.

The anode of diode 303 is connected to the cathode of diode 301 the positive side of capacitor 305, and one end of transformer 307. The cathode of diode 304 is connected to the cathode of diode 303, the positive side of capacitor 305, and the positive primary side of transformer 307.

The positive side of capacitor 305 is connected to the cathode of diode 303, the cathode of diode 304, and the positive side of transformer 307. The negative side of capacitor 305 is connected to the anode of diode 301, the anode of diode 302, and one end of switch 312.

The anode of diode 306 is connected to the secondary positive side of transformer 307. The cathode of diode 306 is connected to the positive side of capacitor 309, the input of DC-DC converter 310, the input of DC-DC converter 311, and terminal 206.

The primary positive side of transformer 307 is connected to the cathode of diode 301, the anode of diode 303, and the positive side of capacitor 305. The primary negative side of transformer 307 is connected to one end of switching element 312. The secondary positive side of transformer 307 is connected to the anode of diode 306. The negative secondary terminal of transformer 307 is connected to the negative side of capacitor 309, the GND of DC/DC converter 310, the GND of DC/DC converter 311, and terminal 207.

One end of switching element 312 is connected to the negative primary side of transformer 307. The other end of switching element 312 is connected to the anode of diode 301 anode of diode 302, and the negative side of capacitor 305. The control terminal of switching element 312 is connected to the output of controller 308.

The positive side of the capacitor 309 is connected to the cathode of the diode 306, the input of the DC-DC converter 310, the input of the DC-DC converter 311, and terminal 206. The negative side of the capacitor 309 is connected to the secondary negative terminal of the transformer 307, the GND of the DC-DC converter 310, the GND of the DC-DC converter 311, and terminal 207.

The input of the DC-DC converter 310 is connected to the cathode of the diode 306, the positive side of the capacitor 309, the input of the DC-DC converter 311, and terminal 206. The output of the DC-DC converter 310 is connected to terminal 210. The GND of the DC-DC converter 310 is connected to the negative side of the capacitor 309, and the secondary negative terminal of the transformer 307 are connected to the GND of the DC-DC converter 311 and terminal 207.

The input of DC-DC converter 311 is connected to the positive side of capacitor 309, the cathode of diode 306, the input of DC-DC converter 310, and terminal 206. The output of DC-DC converter 311 is connected to the outside. The GND of DC-DC converter 311 is connected to the negative side of capacitor 309, and the secondary negative terminal of transformer 307 are connected to the GND of DC-DC converter 310 and terminal 207.

Terminal 206 is connected to the positive side of capacitor 309, the cathode of diode 306, the input of DC-DC converter 310, and the input of DC-DC converter 311. Terminal 210 is connected to the output of DC-DC converter 310. Terminal 207 is connected to the negative side of capacitor 309, and the secondary negative terminal of transformer 307, the GND of DC-DC converter 310 and the GND of DC-DC converter 311.

FIG. 5(a) is a circuit diagram of an nMOS inverter. FIG. 5(b) is a circuit diagram of a pMOS inverter.

One end of resistor 401 is connected to the outside. The other end of resistor 401 is connected to the drain and output of nMOS inverter.

The source of nMOS field effect transistor 402 is connected to the outside. The gate of nMOS field effect transistor 402 is connected to the input. The drain of nMOS field effect transistor 402 is connected to one end of resistor 401 and the output.

The source of pMOS field effect transistor 403 is connected to the outside. The gate of the pMOS field effect transistor 403 is connected to the input. The drain of the pMOS field effect transistor 403 is connected to one end of the resistor 404, the output.

One end of the resistor 404 is connected to the drain of the pMOS field effect transistor 403, the output. The other end of the resistor 404 is connected to the outside.

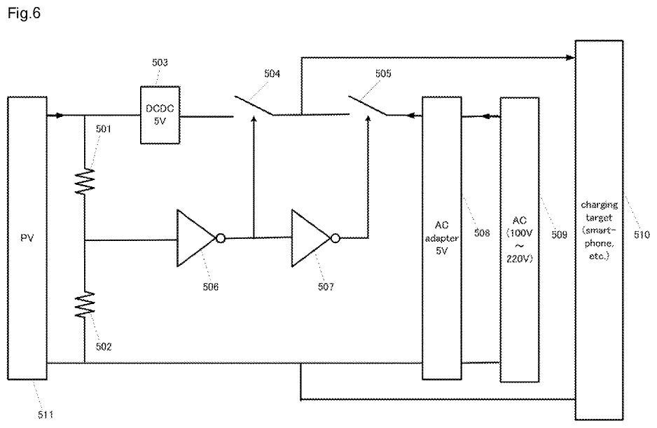

FIG. 6 is a circuit diagram showing a basic coordinated power supply. The positive side of the solar module 511 is connected to the positive side of the resistor 501, the input of the DC-DC converter 503. The negative side of the solar module 511 is connected to GND.

One end of resistor 501 is connected to the positive side of solar module 511 and the input of DC/DC converter 503. The other end of resistor 501 is connected to one end of resistor 502 and the input of inverter 506.

One end of resistor 502 is connected to one end of resistor 501 and the input of inverter 506. The other end of resistor 502 is connected to GND.

The input of DC/DC converter 503 is connected to the positive side of solar module 511 and one end of resistor 501. The output of DC/DC converter 503 is connected to one end of switching element 504.

One end of switching element 504 is connected to the output of DC/DC converter 503. The other end of switching element 504 is connected to one end of switching element 505. The control terminal of switching element 504 is connected to the output of inverter 506 and the input of inverter 507.

One end of the switching element 505 is connected to one end of the switching element 504 and the positive side of the charging target 510. The other end of the switching element 505 is connected to the positive side of the AC adapter 508. The control terminal of the switching element 505 is connected to the output of the inverter 507.

The input of the pMOS type inverter 506 is connected to one end of the resistor 501 and the other end of the resistor 502. The output of the pMOS type inverter 506 is connected to the control terminal of the switching element 504 and the input of the inverter 507. The input of the pMOS type inverter 507 is connected to the control terminal of the switching element 504 and the output of the inverter 506. The output of the inverter 507 is connected to the control terminal of the switching element 505.

The output positive side of the AC adapter 508 is connected to the switching element 505. The output negative side of the AC adapter 508 is connected to GND. The positive input side of the AC adapter 508 is connected to positive of the commercial power supply 509. The negative input side of the AC adapter 508 is connected to GND.

The positive output side of the commercial power supply 509 is connected to the positive input side of the AC adapter 508. The negative output side of the AC adapter 509 is connected to GND.

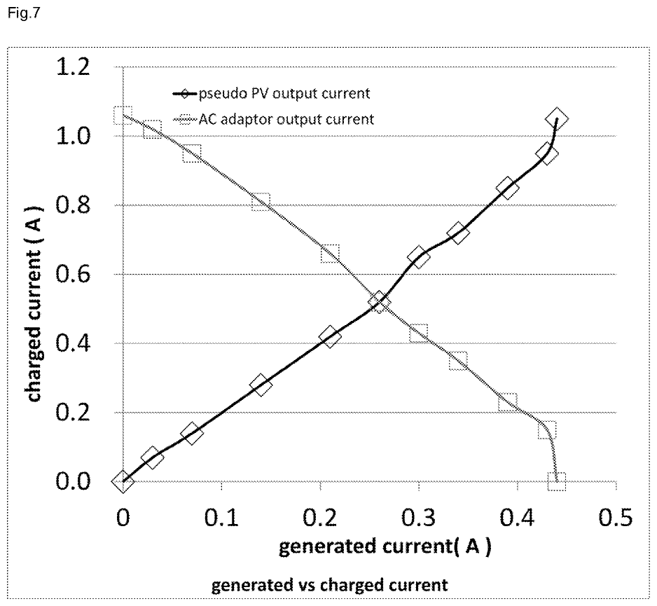

FIG. 7 shows the relationship between the input generated current, the pseudo PV output current, and the AC adapter output current in the coordinated charging circuit of FIG. 6. The pseudo PV output current extends from the bottom left to the top right. The AC adapter output current extends from the top left to the bottom right.

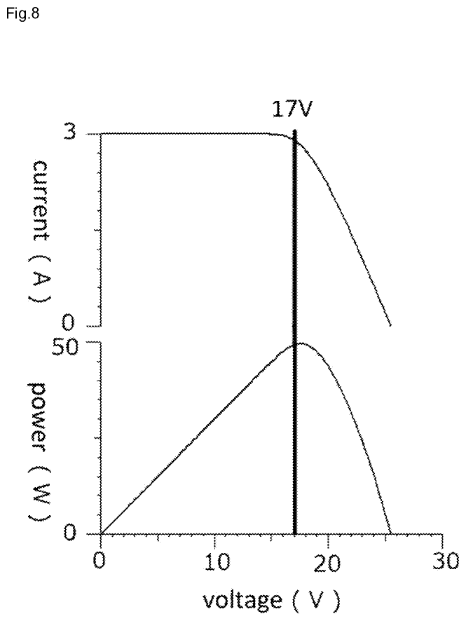

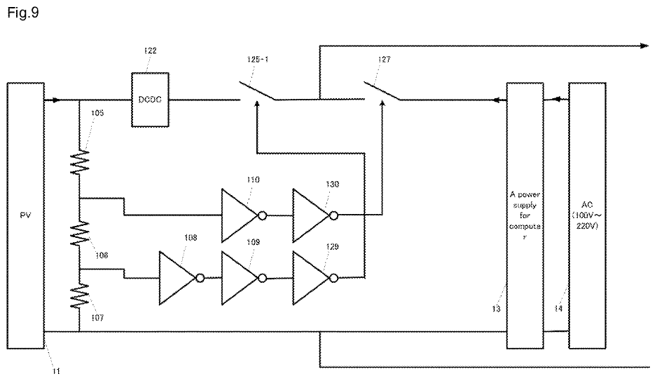

FIG. 8 shows the relationship between the voltage across the solar module, the current drawn from the solar module, and the power that can be drawn from the solar module.

FIG. 9 is a simplified diagram of the configuration in the first embodiment. Although FIG. 9 is basically equivalent to FIGS. 1 and 2, it is a diagram for understanding the outline in the process of understanding the present invention.

The configuration in the first embodiment is composed of the solar module 11, resistors 105, 106, and 107, the DC-DC converter 122, the inverter 108, the inverter 109, the inverter 110, the inverter 129, and the inverter 130, the switching element 125-1, the switching element 127, the power supply for computer (PC) 13, and the commercial AC 14.

The positive side of the solar module 11 is connected to one end of the resistor 105 and the DC-DC converter 122. The negative side of the solar module 11 is connected to GND.

One end of the resistor 105 is connected to the positive side of the solar module 11 and the DC-DC converter 122. The other end of the resistor 105 is connected to one end of the resistor 106 and the input of the inverter 110.

One end of the resistor 106 is connected to one end of the resistor 105 and the input of the inverter 110. The other end of the resistor 106 is connected to one end of the resistor 107 and the input of the inverter 108.

One end of the resistor 107 is connected to one end of the resistor 106 and the input of the inverter 108. The other end of the resistor 107 is connected to GND.

The input of the DC-DC converter 122 is connected to the positive side of the solar module 11 and one end of the resistor 105. The output of the DC-DC converter 122 is connected to one end of the switching element 125-1.

The input of inverter 110 is connected to one end of resistor 105 and one end of resistor 106. The output of inverter 110 is connected to the input of inverter 130.

The input of inverter 108 is connected to one end of resistor 106 and one end of resistor 107. The output of inverter 108 is connected to the input of inverter 109.

The input of inverter 109 is connected to the output of inverter 108. The output of inverter 109 is connected to the input of inverter 129.

The input of inverter 130 is connected to the output of inverter 110. The output of inverter 130 is connected to the control terminal of switching element 127.

The input of inverter 129 is connected to the output of inverter 109. The output of inverter 129 is connected to the control terminal of switching element 125-1.

The input of switching element 125-1 is connected to the output of DC-DC converter 122. The output of switching element 125-1 is connected to the output of switching element 127, the output of FIG. 9. The control terminal of switching element 125-1 is connected to the output of inverter 129.

The input of switching element 127 is connected to the positive side of power supply for computer (PC) 13. The output of the switching element 127 is connected to the output of the switching element 125-1, external to FIG. 9. The control terminal of the switching element 127 is connected to the inverter 130.

The input positive side of the power supply for computer (PC) 13 is connected to the positive side of the commercial power supply 14. The input negative side of the power supply for computer (PC) 13 is connected to the negative side of the commercial power supply 14. The output positive side of the power supply for computer (PC) 13 is connected to the input of the switching element 127. The output negative side of the power supply for computer (PC) 13 is connected to GND.

The positive side of the commercial power supply 14 is connected to the input positive side of the power supply for computer (PC) 13. The negative side of the commercial power supply 14 is connected to the input negative side of the power supply for computer (PC) 13.

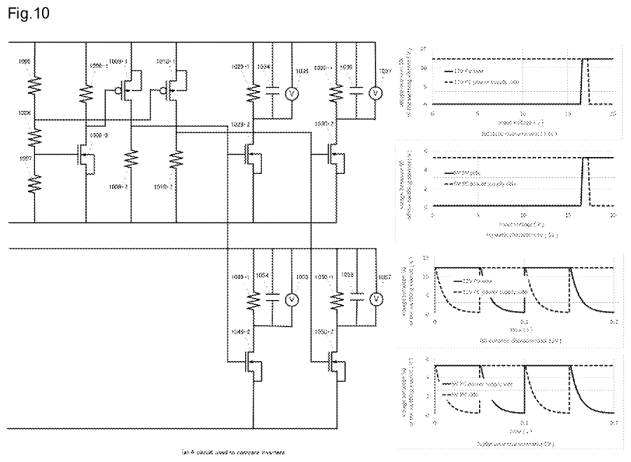

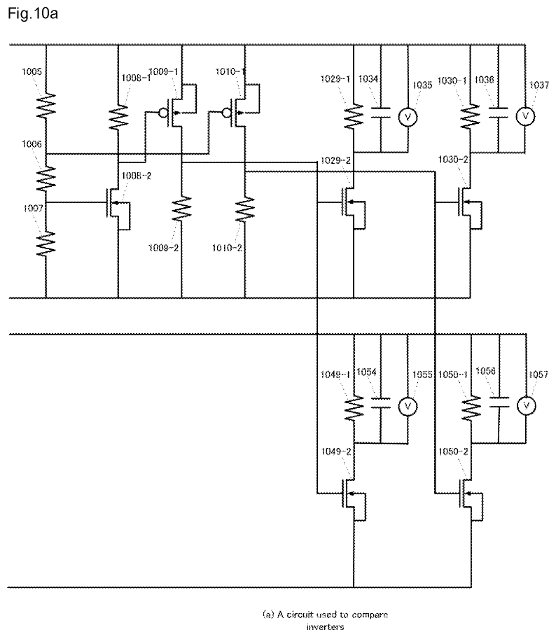

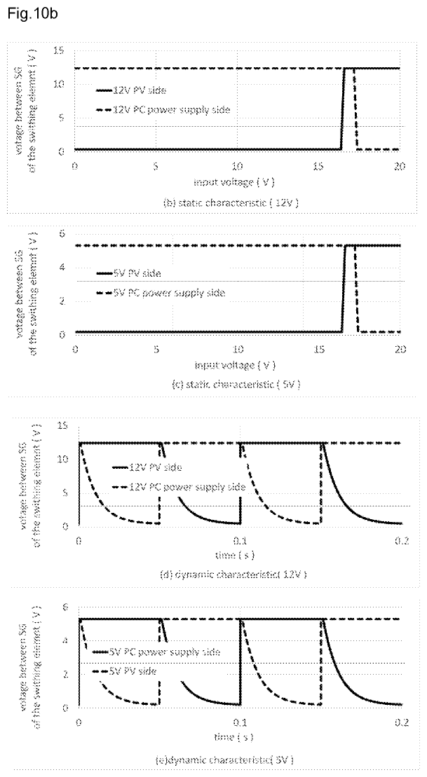

FIG. 10 shows the circuit used to compare the inverters of the circuit A and the simulation results. FIG. 10(a) is a circuit diagram used in the simulation of the circuit A. FIG. 10(b) shows the results of a 12V simulation of the static characteristics of circuit A. FIG. 10(c) shows the results of a 5V simulation of the static characteristics of circuit A. FIG. 10(d) shows the results of a 12V simulation of the dynamic characteristics of circuit A. FIG. 10(e) shows the results of a 5V simulation of the dynamic characteristics of circuit A. FIG. 10(a) is a diagram used in the simulation, and is not a diagram that is believed to be the best, so the details of the connection will not be described.

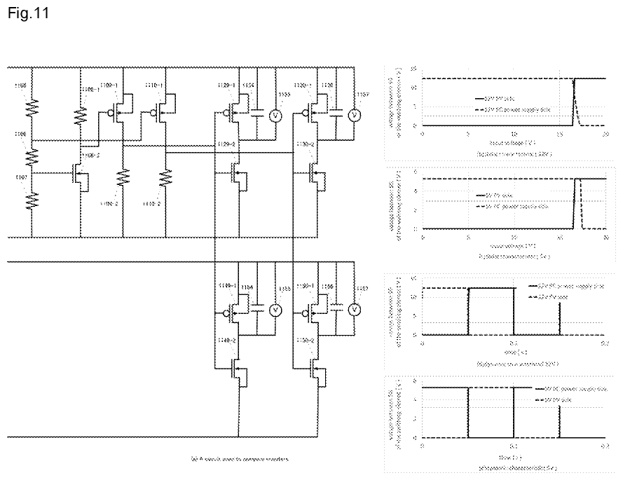

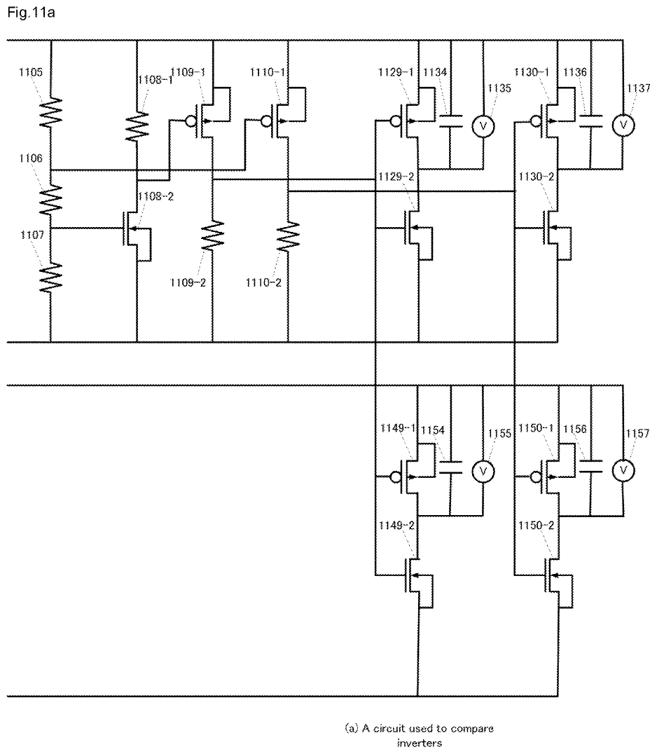

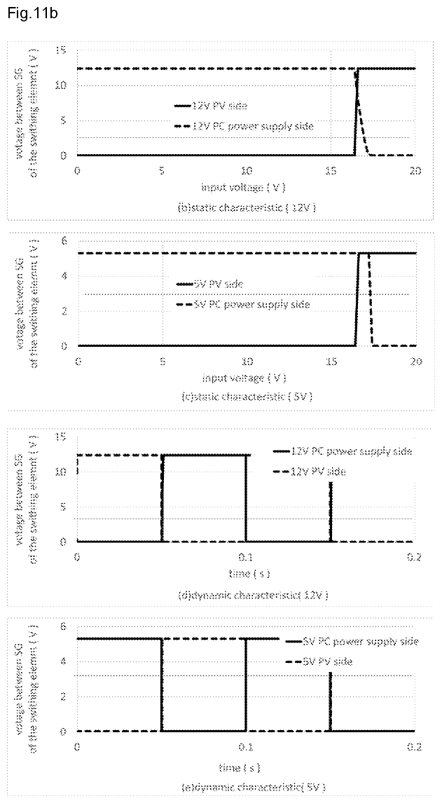

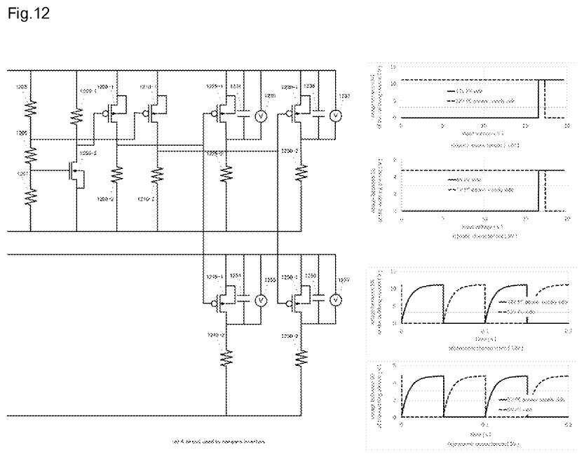

FIG. 11 shows the circuit used to compare inverters in circuit I and the simulation results. FIG. 11(a) shows the circuit diagram used in the simulation of circuit I. FIG. 11(b) shows the results of a 12V simulation of the static characteristics of circuit I. FIG. 11(c) shows the results of a 5V simulation of the static characteristics of circuit I. FIG. 11(d) shows the results of a 12V simulation of the dynamic characteristics of circuit I. FIG. 11(e) shows the results of a 5V simulation of the dynamic characteristics of circuit I. FIG. 11(a) is a diagram used in the simulation, and is not drawn as a circuit believed to be the best, so the details of the connections will not be described.

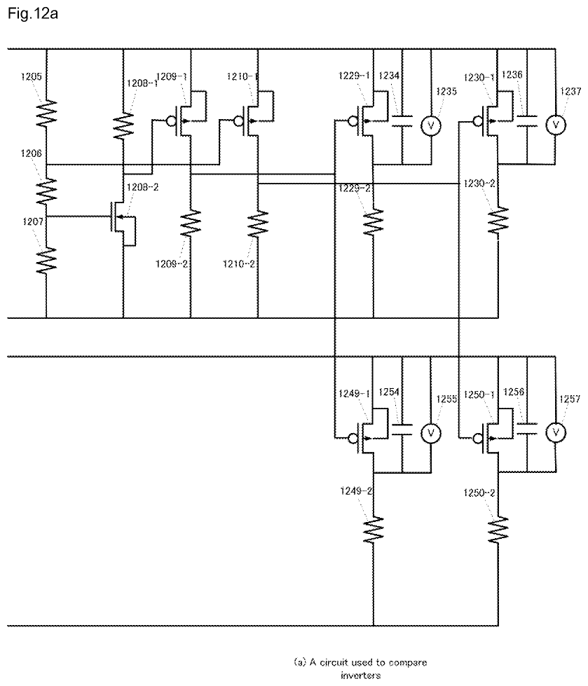

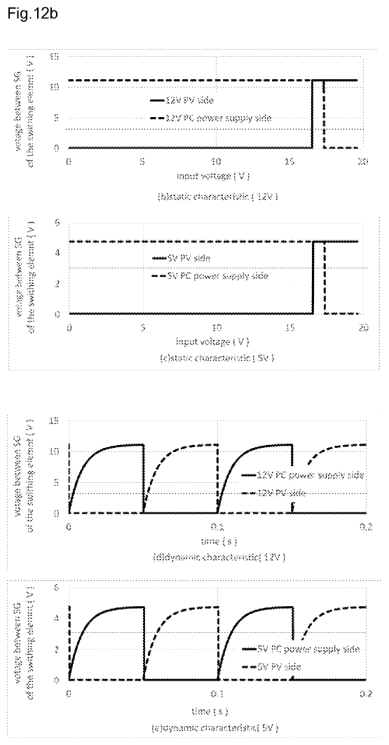

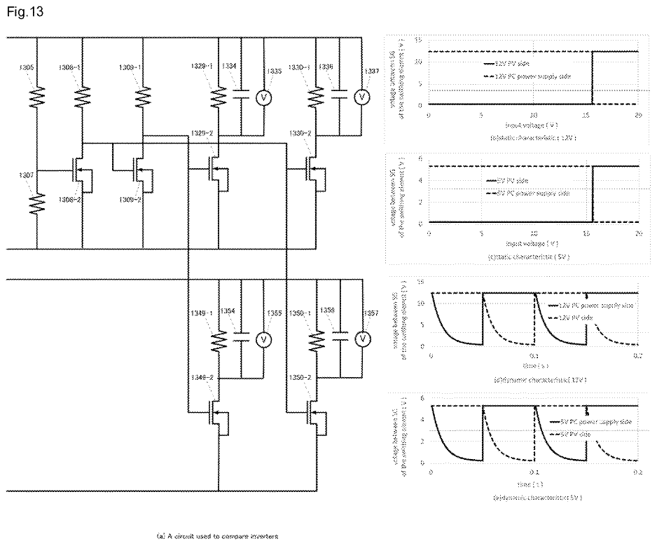

FIG. 12 shows the circuit used to compare the inverters in circuit U and the simulation results. FIG. 12(a) is a circuit diagram used in the simulation of circuit U. FIG. 12(b) is a simulation result of the static characteristics of circuit U at 12 V. FIG. 12(c) is a simulation result of the static characteristics of circuit U at 5 V. FIG. 12(d) is a simulation result of the dynamic characteristics of circuit U at 12 V. FIG. 12(e) is a simulation result of the dynamic characteristics of circuit U at 5 V. FIG. 12(a) is a diagram used in the simulation, and is not drawn as a circuit believed to be the best, so the details of the connections will not be described.

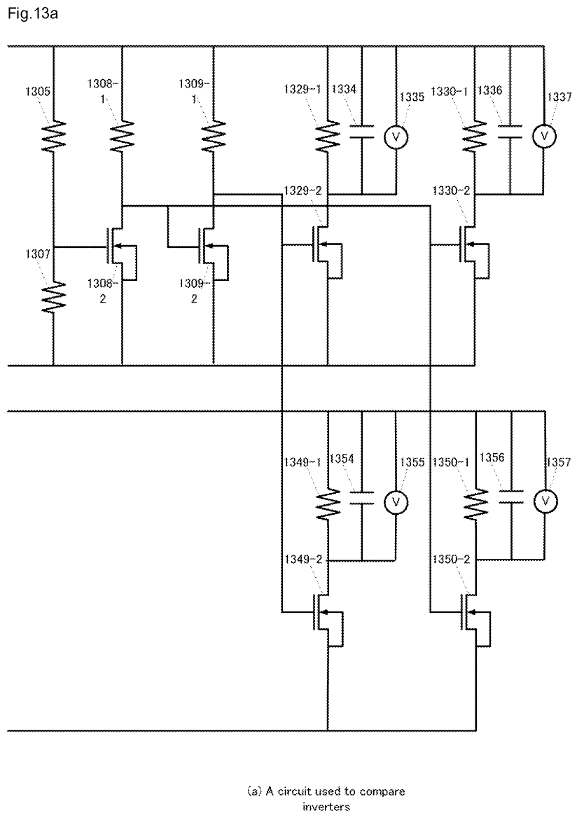

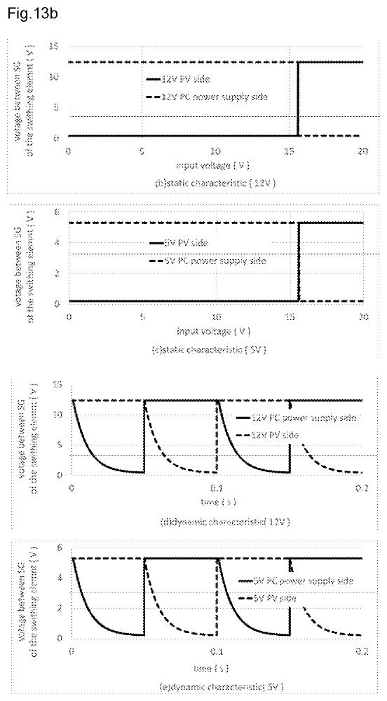

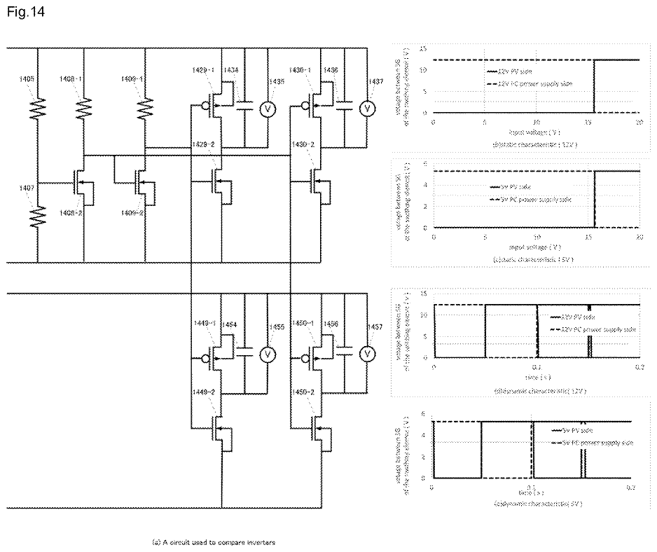

FIG. 13 shows the circuit used to compare the inverters of circuit E and the simulation results. FIG. 13(a) is a circuit diagram used in the simulation of circuit E. FIG. 13(b) is a simulation result of the static characteristics of circuit E at 12V. FIG. 13(c) is a simulation result of the static characteristics of circuit E at 5V. FIG. 13(d) is a simulation result of the dynamic characteristics of circuit E at 12V. FIG. 13(e) is a simulation result of the dynamic characteristics of circuit E at 5V. FIG. 13(a) is a diagram used in the simulation and is not drawn as the circuit believed to be the best, so the details of the connection will not be explained.

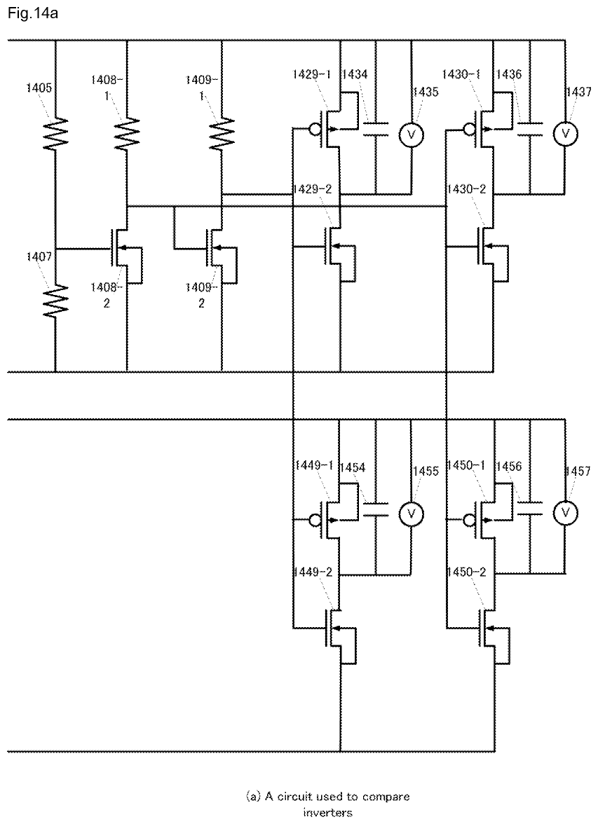

FIG. 14 shows the circuit used to compare the inverters of circuit O and the simulation results. FIG. 14(a) is a circuit diagram used in the simulation of circuit O. FIG. 14(b) is a simulation result of the static characteristics of circuit O at 12V. FIG. 14(c) is a simulation result of the static characteristics of circuit O at 5V. FIG. 14(d) shows the results of a 12V simulation of the dynamic characteristics of circuit O. FIG. 14(e) shows the results of a 5V simulation of the dynamic characteristics of circuit O. FIG. 14(a) is a diagram used in the simulation, and is not a circuit that is believed to be the best, so the details of the connections will not be described.

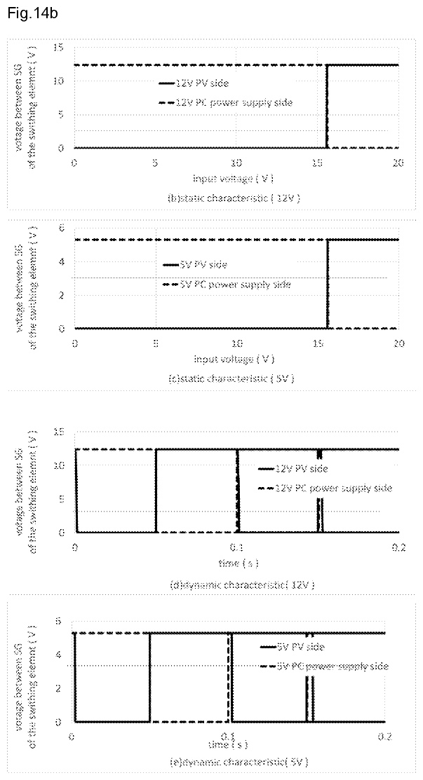

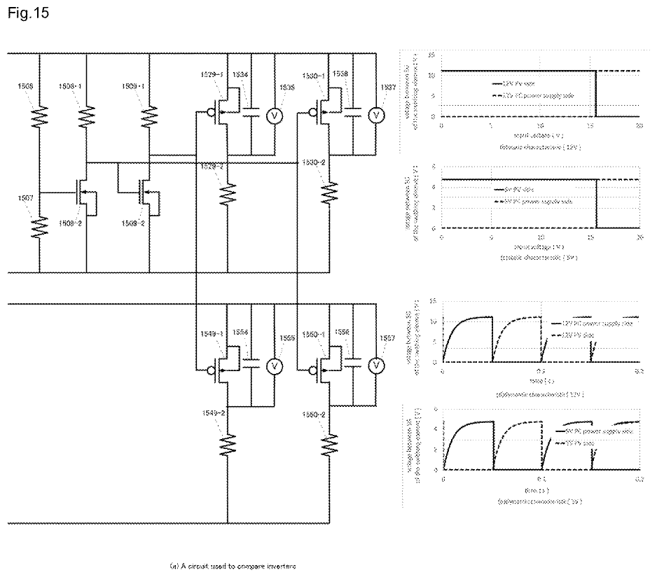

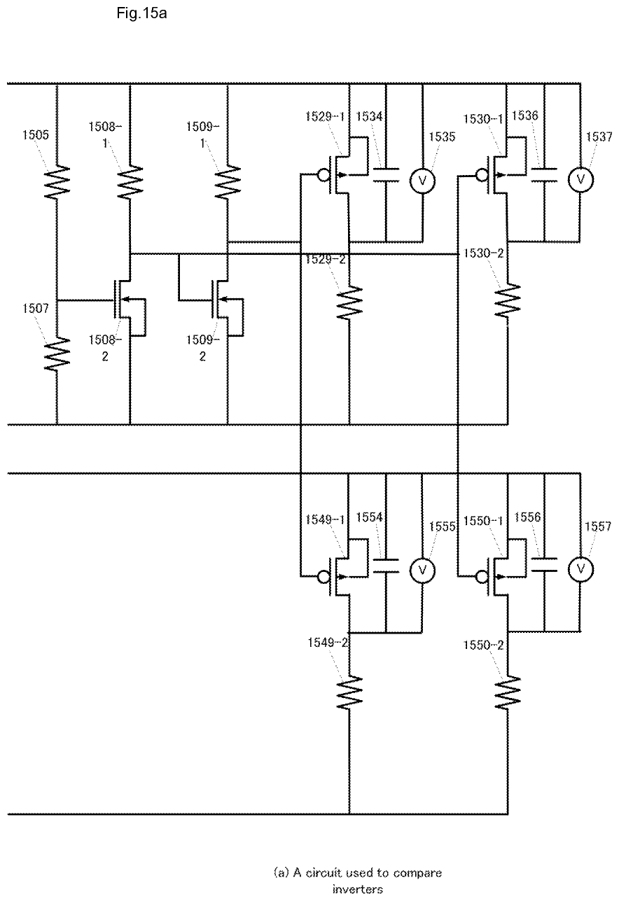

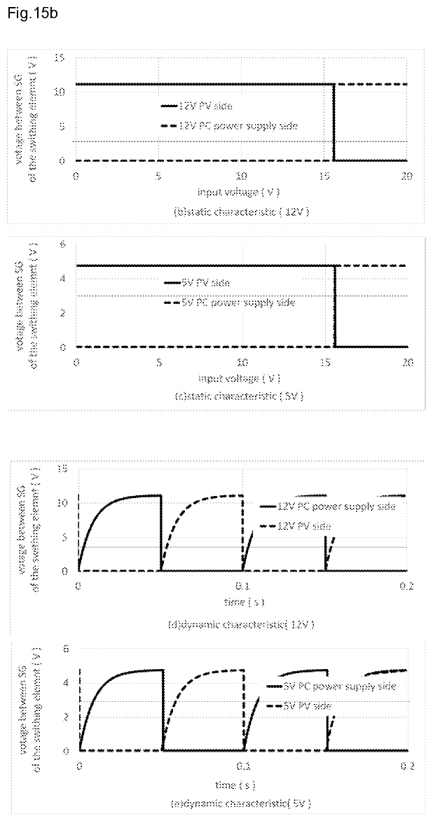

FIG. 15 shows the circuit used to compare the inverters of circuit Ka and the simulation results. FIG. 15(a) is a circuit diagram used in the simulation of circuit Ka. FIG. 15(b) shows the results of a 12V simulation of the static characteristics of circuit Ka. FIG. 15(c) shows the results of a 5V simulation of the static characteristics of circuit 1. FIG. 15(d) shows the results of a 12V simulation of the dynamic characteristics of circuit Ka. FIG. 15(e) shows the results of a 5V simulation of the dynamic characteristics of circuit Ka. FIG. 15(a) is a diagram used in the simulation, and is not a circuit that is believed to be the best, so the details of the connections will not be described.

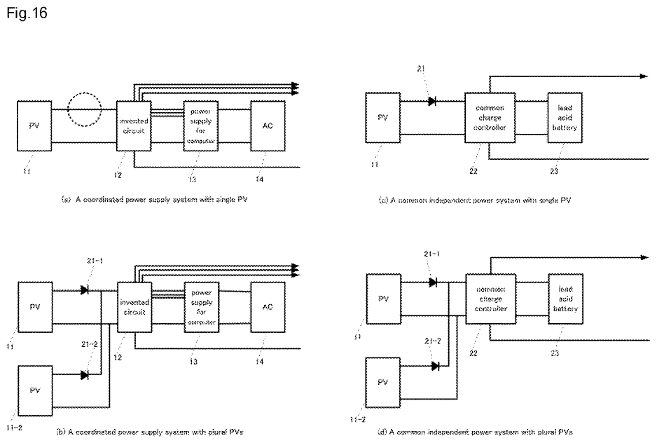

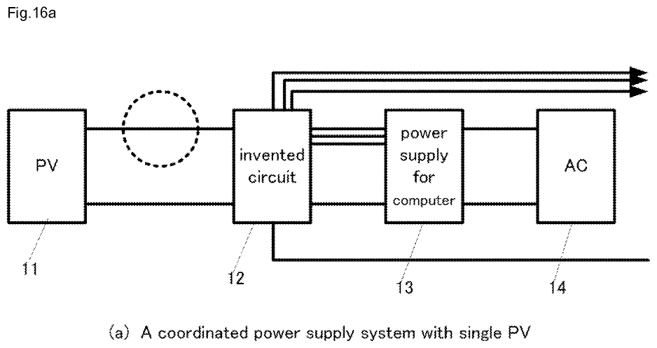

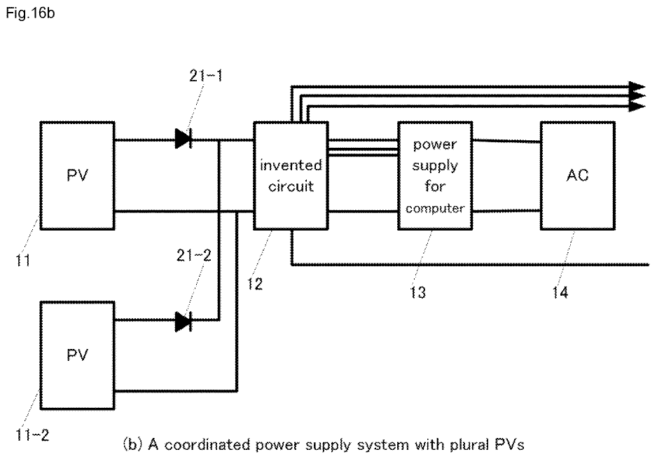

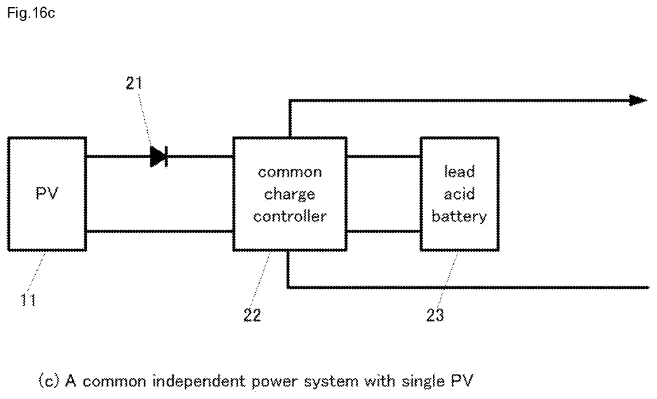

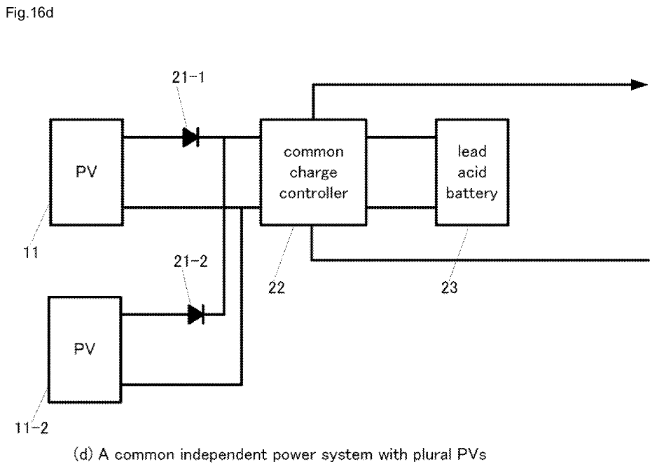

FIG. 16 is an explanatory diagram of cases where a reverse current prevention diode is necessary and not necessary. FIG. 16(a) is a schematic connection diagram of a coordinated charging system with one solar module. A reverse current prevention diode is not necessary. FIG. 16(b) is a schematic connection diagram of a coordinated charging system with two solar modules. A reverse current prevention diode is necessary for each solar module. 16(c) is a schematic connection diagram of a general independent power system with one solar module. A reverse current prevention diode is necessary even with one solar module. 16(d) is a schematic connection diagram of a general independent power system with two solar modules. A reverse current prevention diode is necessary for each solar module. Detailed explanation of the connections in FIG. 16 is omitted.

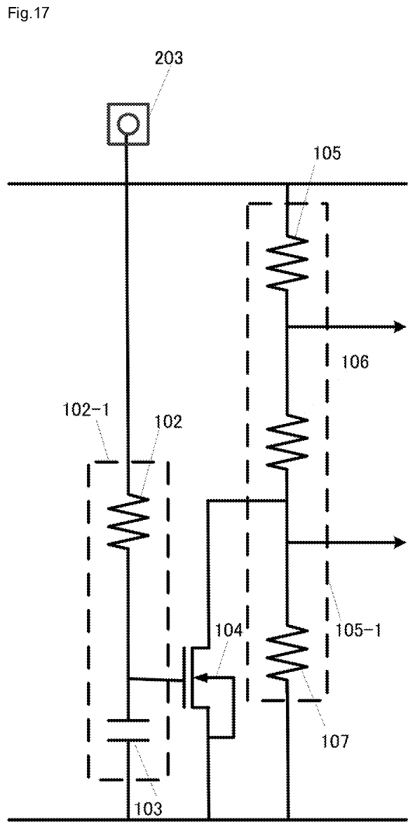

FIG. 17 is a circuit diagram of the part that links with the power button of the computer (PC). FIG. 17 is a part of FIG. 2. The connection of the circuit in FIG. 17 has been explained in FIG. 2, so the explanation of the connection in FIG. 17 is omitted.

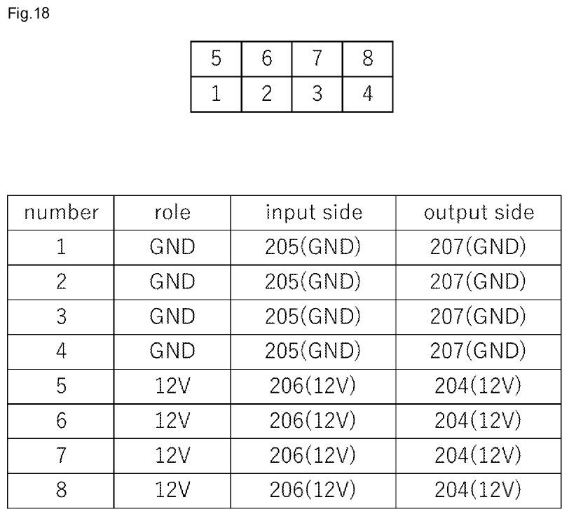

FIG. 18 shows the pin assignment of the CPU power connector. As of 2025, the most common CPU power connectors are 8-pin configurations. Therefore, in this embodiment, the explanation will be given assuming 8 pins. Connectors with 4-pin configurations also exist, but the concept is similar.

The role of pin 1 is GND, and in this embodiment, the input side is connected to 205 (GND), and the output side is connected to 207 (GND). The role of pin 2 is GND, and in this embodiment, the input side is connected to 205 (GND), and the output side is connected to 207 (GND). The role of pin 3 is GND, and in this embodiment, the input side is connected to 205 (GND), and the output side is connected to 207 (GND). The role of pin 4 is GND, and in this embodiment, the input side is connected to 205 (GND), and the output side is connected to 207 (GND).

The role of pin 5 is 12V, and in this embodiment, the input side is connected to 206 (12V), and the output side is connected to 204 (12V). The role of pin 6 is 12V, and in this embodiment, the input side is connected to 206 (12V), and the output side is connected to 204 (12V). The role of pin 7 is 12V, and in this embodiment, the input side is connected to 206 (12V), and the output side is connected to 204 (12V). The role of pin 8 is 12V, and in this embodiment, the input side is connected to 206 (12V), and the output side is connected to 204 (12V).

In this way, an 8-pin CPU power connector has four 12V pins and four GND pins. A 4-pin CPU power connector has two 12V pins and two GND pins.

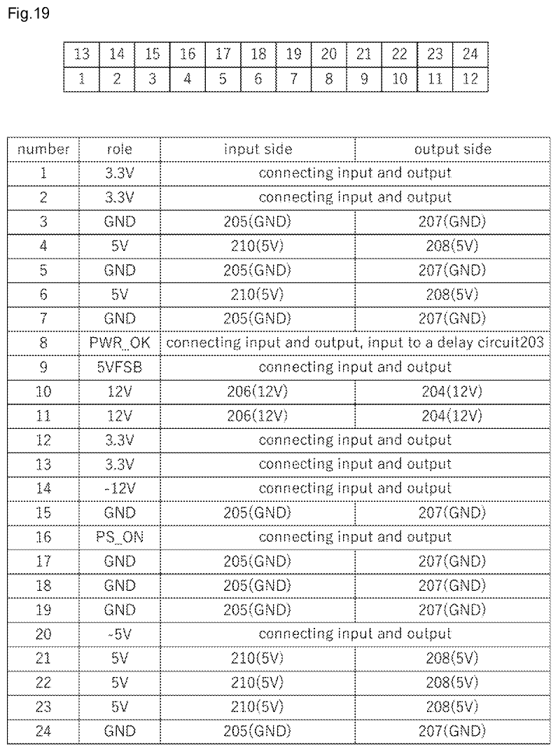

FIG. 19 shows the pin assignment of a motherboard power connector. As of 2025, the most common motherboard power connectors are 24-pin configurations. Therefore, this embodiment will be explained assuming 24 pins. Connectors with 20 pin configurations also exist, but the concept is similar.

Pin 1 has a role of 3.3V, and in this embodiment, connects the input side and the output side. Pin 2 has a role of 3.3V, and in this embodiment, connects the input side and the output side. Pin 3 has a role of GND, and in this embodiment, the input side is connected to 205 (GND) and the output side is connected to 207 (GND). Pin 4 has a role of 5V, and in this embodiment, the input side is connected to 210 (5V) and the output side is connected to 208 (5V).

Pin 5 has a role of GND, and in this embodiment, the input side is connected to 205 (GND) and the output side is connected to 207 (GND). Pin 6 has a role of 5V, and in this embodiment, the input side is connected to 210 (5V) and the output side is connected to 208 (5V). Pin 7 has the role of GND, and in this embodiment, the input side is connected to 205 (GND), and the output side is connected to 207 (GND). Pin 8 has the role of PWR_OK (power OK), and receives a signal indicating whether the power is on. In this embodiment, it connects the input side and the output side, and is further connected to terminal 203 toward the delay circuit. Pin 9 has the role of 5 VFSB (5 volt FSB), and supplies 5V even when the computer (PC) is turned off. In this embodiment, it connects the input side and the output side. Pin 10 has the role of 12V, and in this embodiment, the input side is connected to 206 (12V), and the output side is connected to 204 (12V). Pin 11 has the role of 12V, and in this embodiment, the input side is connected to 206 (12V), and the output side is connected to 204 (12V). The role of pin 12 is 3.3V, and it connects the input side and the output side.

The role of pin 13 is 3.3V, and in this embodiment, it connects the input side and the output side. The role of pin 14 is −12V, and in this embodiment, it connects the input side and the output side. The role of pin 15 is GND, and in this embodiment, the input side is connected to 205 (GND), and the output side is connected to 207 (GND). The role of pin 16 is PS_ON, and it is a terminal for turning on the power supply, and in this embodiment, it connects the input side and the output side.

The role of pin 17 is GND, and in this embodiment, the input side is connected to 205 (GND), and the output side is connected to 207 (GND). The role of pin 18 is GND, and in this embodiment, the input side is connected to 205 (GND), and the output side is connected to 207 (GND). The role of pin 19 is GND, and in this embodiment, the input side is connected to 205 (GND), and the output side is connected to 207 (GND). The role of pin 20 is −5V, and in this embodiment, it connects the input and output.

The role of pin 21 is 5V, and in this embodiment, the input side is connected to 210 (5V), and the output side is connected to 208 (5V). The role of pin 22 is 5V, and in this embodiment, the input side is connected to 210 (5V), and the output side is connected to 208 (5V). The role of pin 23 is 5V, and in this embodiment, the input side is connected to 210 (5V), and the output side is connected to 208 (5V). Pin 24 serves as GND, and in this embodiment, the input side is connected to 205 (GND), and the output side is connected to 207 (GND).

The 20-pin motherboard power connector is composed of only pins 1 to 10 and pins 13 to 22 of the 24-pin motherboard power connector.

There are six types of power supplies: 12V, normal 5V, always-on 5V (5 VFSB), 3.3V,-5V, and −12V. In this embodiment, only 12V and normal 5V are used for coordinated power supply, and for always-on 5V (5 VFSB), 3.3V, −5V, and −12V, the input and output are simply connected.

The reason is that 12V and normal 5V handle a lot of power, while always-on 5V (5 VFSB), 3.3V, −5V, and −12V handle less power. Even if the power handled is small, if a dedicated DC-DC converter is prepared, a certain amount of power is required even with no load or low load. This reduces power efficiency.

PWR_OK is a signal line that receives whether power is being supplied from the power supply for computer (PC). PWR_OK indicates that there is power being supplied from the power supply for computer (PC) when it is L (low), and indicates that there is no power being supplied from the power supply for computer (PC) when it is H (high). A delay is created in the resistor 102, capacitor 103, and nMOS field effect transistor 104 parts in FIGS. 2 and 17. When the PWR_OK signal changes from L (low) to H (high), the power supply from the solar module 11 ends after a certain time delay. When the WR_OK signal changes from H (high) to L (low), power supply from the solar module 11 starts after a certain time delay.

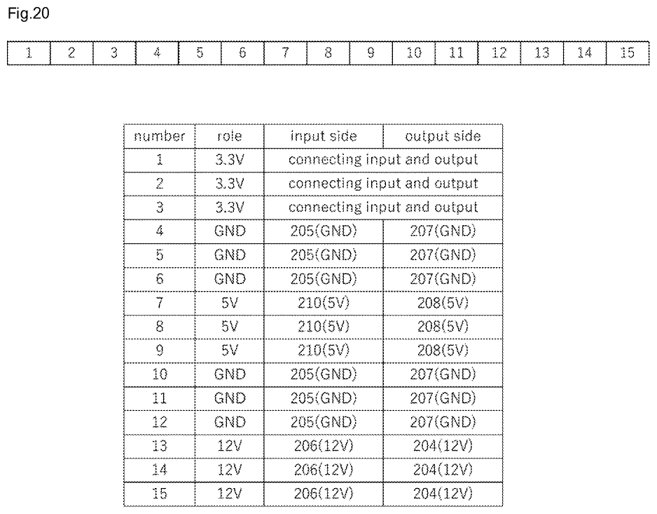

FIG. 20 shows the wiring assignment of a storage power connector. The most common storage power connectors as of 2025 have a 15-pin connector and a 5-pin wiring. Therefore, in this embodiment, the explanation is based on the assumption that there are 15 connector pins and 5 wiring pins.

Pin 1 has a role of 3.3V, and in this embodiment, it connects the input side and the output side. Pin 2 has a role of 3.3V, and in this embodiment, it connects the input side and the output side. Pin 3 has a role of 3.3V, and in this embodiment, it connects the input side and the output side. Pins 1, 2, and 3 are connected to the same wiring.

Pin 4 has a role of GND, and in this embodiment, the input side is connected to 205 (GND) and the output side is connected to 207 (GND). Pin 5 has a role of GND, and in this embodiment, the input side is connected to 205 (GND) and the output side is connected to 207 (GND). Pin 6 has a role of GND, and in this embodiment, the input side is connected to 205 (GND) and the output side is connected to 207 (GND). Pins 4, 5, and 6 are connected to the same wiring.

Pin 7 has the role of 5V, and in this embodiment, the input side is connected to 210 (5V), and the output side is connected to 208 (5V). Pin 8 has the role of 5V, and in this embodiment, the input side is connected to 210 (5V), and the output side is connected to 208 (5V). Pin 9 has the role of 5V, and in this embodiment, the input side is connected to 210 (5V), and the output side is connected to 208 (5V). Pins 7, 8, and 9 are connected to the same wiring.

Pin 10 has the role of GND, and in this embodiment, the input side is connected to 205 (GND), and the output side is connected to 207 (GND). The role of pin 11 is GND, and in this embodiment, the input side is connected to 205 (GND), and the output side is connected to 207 (GND). The role of pin 12 is GND, and in this embodiment, the input side is connected to 205 (GND), and the output side is connected to 207 (GND). Pins 10, 11, and 12 are connected to the same wiring.

The role of pin 13 is 12V, and in this embodiment, the input side is connected to 206 (12V), and the output side is connected to 204 (12V). The role of pin 14 is 12V, and in this embodiment, the input side is connected to 206 (12V), and the output side is connected to 204 (12V). The role of pin 15 is 5V, and in this embodiment, the input side is connected to 206 (12V), and the output side is connected to 204 (12V). Pins 13, 14, and 15 are connected to the same wire.

The storage power connector uses three types of power: 12V, 5V, and 3.3V. Of these, 3.3V is used only in some storage devices, such as 1.8-inch hard disks. Note that some M 2-type SSDs use 3.3V, but since power is supplied from the motherboard, storage power connectors often do not supply 3.3V.

In this embodiment, 12V and 5V are supplied with power from solar modules. This is because 12V and 5V handle large amounts of power.

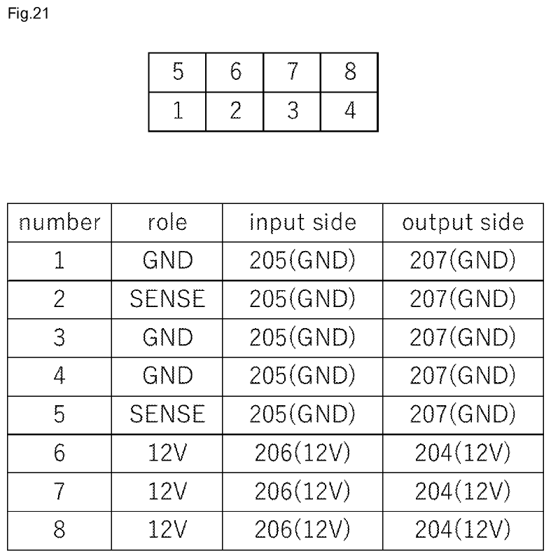

FIG. 21 shows the pin assignment of the graphics board power connector. The most common graphics board power connectors as of 2025 are the 6-pin and 8-pin types. The 6-pin type is designed to supply up to 75 W of power, and the 8-pin type is designed to supply up to 150 W of power.

The role of pin 1 is GND, and in this embodiment, the input side is connected to 205 (GND), and the output side is connected to 207 (GND). The role of pin 2 is SENSE, and it is used to inform the graphics board of the power that can be supplied. In this embodiment, the input side is connected to 205 (GND), and the output side is connected to 207 (GND). The role of pin 3 is GND, and in this embodiment, the input side is connected to 205 (GND), and the output side is connected to 207 (GND). The role of pin 4 is GND, and in this embodiment, the input side is connected to 205 (GND), and the output side is connected to 207 (GND). The role of pin 5 is SENSE, and it is used to inform the graphics board of the power that can be supplied. The role of pin 6 is 12V, and in this embodiment, the input side is connected to 206 (12V) and the output side is connected to 204 (12V). The role of pin 7 is 12V, and in this embodiment, the input side is connected to 206 (12V) and the output side is connected to 204 (12V). The role of pin 8 is 12V, and in this embodiment, the input side is connected to 206 (12V) and the output side is connected to 204 (12V).

The role of pins 2 and 5 is SENSE, and when both are connected to GND, it clearly indicates that up to 150 W of power can be supplied. I do not know if this is generally the case, but in my experiments, even when pins 2 and 5 are connected to GND, if power is not supplied to the graphics board power connector, the graphics board may be permanently damaged. Therefore, care must be taken when supplying power to the graphics board using the circuit and method of the this invention.

Most CPUs have built-in graphics functions, and computers (PCs) often operate without a dedicated graphics board. Even when a dedicated graphics board is used, if the dedicated graphics board consumes little power, the dedicated graphics board can operate with only the power supply from the motherboard without supplying power using the graphics board power connector.

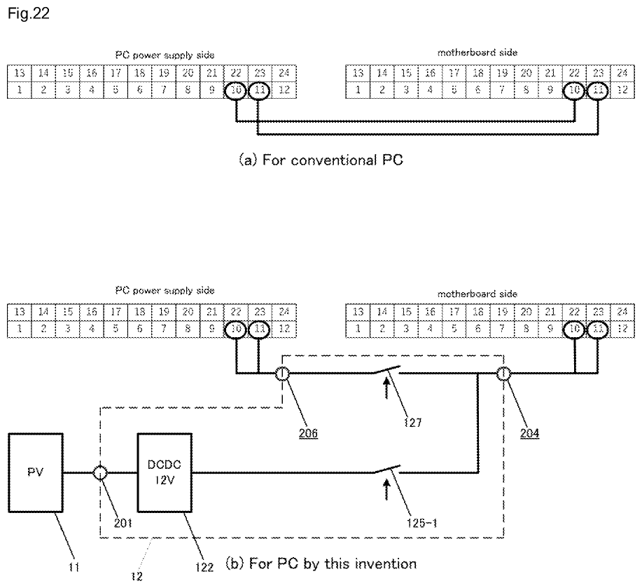

FIG. 22 shows the relationship between the power connector and the circuit of the present invention.

FIG. 22(a) shows the wiring between the power supply for computer (PC) side connected from the power supply for computer (PC) and the motherboard side connected to the motherboard in a conventional power supply for a motherboard, limited to the 12V part. Simply, pin 10 on the power supply for computer (PC) side is connected to pin 10 on the motherboard side, and pin 11 on the power supply for computer (PC) side is connected to pin 11 on the motherboard side.

FIG. 22(b) shows the wiring between the power supply for computer (PC) side connected from the power supply for computer (PC) and the motherboard side connected to the motherboard in a power supply for a motherboard in the present invention, limited to the 12V part. Pins 10 and 11 on the power supply for computer (PC) side are connected to terminal 206. Pins 10 and 11 on the motherboard side are connected to terminal 204. The solar module is connected to terminal 201.

The switching element 127 controls the power from the power supply for computer (PC) and supplies it to the motherboard. Similarly, the switching element 125-1 controls the power from the solar module 11 and supplies it to the motherboard. The switching element 127 and the switching element 125-1 combine the power from the power supply for computer (PC) and the solar module 11 to supply it in a coordinated manner.

In FIG. 22, only the motherboard and 12V are described. However, the same applies to the CPU, storage, and graphic board, and also to 5V. In the case of the present invention, the 12V from the power supply for computer (PC) for the CPU, storage, and graphic board is connected to the terminal 206, and the 12V to the CPU, storage, and graphic board is connected to the terminal 204. For 5V, a similar circuit is prepared in a separate system.

From here, the operation of the system and circuit of this embodiment will be described. FIG. 1 is a block diagram of a first embodiment of the present invention. The solar module 11 generates DC power and supplies it to the main circuit 12. In this embodiment, a 12V solar module is assumed, but the concept is the same for 24V and 48V solar modules.

The DC generated by the solar module 11 has an open voltage, which is the voltage when there is no load, of, for example, 21V, and a short-circuit current, which is the current when the output is short-circuited, of, for example, 5 A. The values given here are assumed examples, and various solar modules can be used. The DC generated by the solar module 11 is, for example, about 17.5V.

AC is supplied from the commercial power source 14. The AC supplied here is 100V to 220V worldwide. It is 100V in Japan, 110V in the United States, and 220V in China. The AC supplied from the commercial power source 14 is supplied to the power supply for computer (PC) 13, which generates 12V, normal 5V, 3.3V, always-on 5V, −5V, and −12V. In this embodiment, 12 V, normal 5 V, is supplied to the main circuit 12. The main circuit 12 receives power from a solar module 11.

The power supplied from the solar module 11 to the main circuit 12 is converted to 12V and 5V in the main circuit 12. In the main circuit 12, the 12V generated in the main circuit 12 and the 12V generated in the power supply for computer (PC) 13 are mixed by coordinated power supply. Coordinated power supply is a technology that mixes the power from the solar module and the power supply for computer (PC), and is based on feedback control. Its characteristic is that the power from the solar module is used preferentially, and the power from the power supply for computer (PC) is used only when the power from the solar module is insufficient.

The 12V power generated by coordinated power supply is supplied to the CPU 15, motherboard 16, storage 17, and GPU auxiliary 18. The 5V power generated by coordinated power supply is supplied to the motherboard 16 and storage 17.

In this embodiment, the 12V generated by the main circuit 12 and the 12V generated by the power supply for computer (PC) are mixed by coordinated power supply to generate coordinated power supply 12V, and the 5V generated by the main circuit 12 and the normal 5V generated by the power supply for computer (PC) are mixed by coordinated power supply to generate coordinated power supply 5V. On the other hand, coordinated power supply is not performed for 3.3V, always-on 5V, −5V, and −12V, and the voltage generated by the power supply for computer (PC) is supplied directly to the motherboard 16 and storage 17.

The reason for this is that while 12V and normal 5V handle large amounts of power, constant connection 5V (5 VFSB), 3.3V, −5V, and −12V handle small amounts of power. Even if the amount of power handled is small, if a dedicated DC-DC converter is prepared, a certain amount of power is required even with no load or low load. Therefore, this reduces the overall power efficiency.

In FIG. 1, the always-on 5V (5 VFSB), −5V, and −12V are omitted, but the always-on 5V (5 VFSB), −5V, and −12V are directly supplied to the motherboard 16 from the power supply for computer (PC).

In this embodiment, as an example that the inventor believes to be the best, only 12V and normal 5V are coordinated for charging, and always-on 5V (5 VFSB), 3.3V, −5V, and −12V are not coordinated for power supply. In some case, only 12V is coordinated, and normal 5V, always-on 5V (5 VFSB), 3.3V, −5V, and −12V do not need to be coordinated for power supply. In this case, the costs of the board, mounted components, and mounting work can be reduced, but the proportion of power that can be supplied from the solar module out of the power consumed by the computer (PC) is reduced.

In some case, conversely, 12V, normal 5V, always-on 5V (5 VFSB), and 3.3V may be fed in a coordinated manner. In this case, the cost of the board, mounted components, and mounting work will be higher, but the proportion of the power consumed by the computer (PC) that can be supplied from the solar module will be greater.

When only 12V and normal 5V are fed in a coordinated manner, for a computer (PC) that consumes 40 W when idle, for example 30 W of the 40 W of power consumed can be supplied from the solar module 11 through coordinated feeding. The remaining 10 W is the power required for always-on 5V (5 VFSB), 3.3V, −5V, −12V, and for controlling the power supply for computer (PC) itself. In this case, even if the solar module generates more than 30 W of power, for example 50 W, only 30 W of power will be used in this system, and the remaining 20 W will be wasted.

When the computer (PC) is used and a load is applied, the power consumed at 12V, usually 5V, increases. In particular, when the load increases on the CPU, etc., the power consumption at 12V increases significantly. In the 12V system, a large current of 10 A or 20 A flows at high load. At that time, the computer (PC) consumes a large amount of power, such as 100 W to 250 W. Most of this can be supplied from the solar module 11 by cooperative power supply. For example, if the power consumption of the computer (PC) is 120 W and the power that can be supplied from the solar module 11 by cooperative power supply is 110 W, if the solar module generates 150 W, 110 W of that is effectively used. For example, if the power consumption of the computer (PC) is 120 W and the power that can be supplied from the solar module 11 by cooperative power supply is 110 W, if the solar module generates 70 W, 70 W is effectively used, and the remaining 40 W is supplied from the power supply for the computer (PC). The power required for the other always-on 5V (5 VFSB), 3.3V, −5V, and −12V is also supplied from the power supply for computer (PC). The power required to control the power supply for computer (PC) is also included, and for example, about 50 W is supplied from the commercial power supply 14.

Next, the operation of the main circuit 12 will be explained using FIG. 2. First, the explanation will be given on the assumption that the signal from terminal 203 is L (low). Since the signal from terminal 203 is L (low), no voltage is applied between the source and gate of the nMOS field effect transistor 104, and the operation is the same as if the nMOS field effect transistor 104 did not exist.

A voltage from a solar module is applied between terminals 201 and 202. Resistive voltage divider 106-1 is composed of resistors 105, 106, and 107, and divides the voltage between terminals 201 and 202.

The node between resistors 106 and 107 is input to nMOS inverter 108, which inverts, amplifies, and outputs the signal. The output of nMOS inverter 108 is input to pMOS inverter 109, which inverts, amplifies, and outputs the signal. The output of pMOS inverter 109 is input to nMOS field effect transistor 129 and nMOS field effect transistor 149.

The output of nMOS inverter 129 is input to pMOS field effect transistor 125 and pMOS field effect transistor 126. The output of the nMOS field effect transistor 149 is input to the pMOS field effect transistor 145 and the pMOS field effect transistor 146.

The node between the resistors 105 and 106 is input to the nMOS inverter 110, which inverts, amplifies, and outputs the signal. The output of the pMOS inverter 110 is input to the nMOS inverter 130 and the nMOS inverter 150.

The input to the terminal 201 is converted to 12V by the DC-DC converter 122 and output to the node 134. The current between the nodes 134 and 135 is adjusted by controlling the outputs of the pMOS field effect transistor 125, the pMOS field effect transistor 126, and the nMOS inverter 129.

The presence of two pMOS field effect transistors, the pMOS field effect transistor 125 and the pMOS field effect transistor 126, makes it possible to control the current in both directions. That is, when the potential of node 134 is higher than the potential of node 135, the output of nMOS inverter 129 controls the current flowing from node 134 to node 135, and when the potential of node 135 is higher than the potential of node 134, the output of nMOS field effect transistor 126 controls the current flowing from node 135 to node 134.

The pMOS field effect transistor 127 adjusts the current between node 136 and node 135.

The input of terminal 201 is converted to 5V by DC-DC converter 142 and output to node 154. The pMOS field effect transistor 145 and pMOS field effect transistor 146 adjust the current between node 154 and node 155.

The presence of two pMOS field effect transistors, pMOS field effect transistor 145 and pMOS field effect transistor 146, makes it possible to control the current in both directions. That is, when the potential of node 154 is higher than the potential of node 155, the pMOS field effect transistor 145 controls the current flowing from node 154 to node 155, and when the potential of node 155 is higher than the potential of node 154, the pMOS field effect transistor 146 controls the current flowing from node 155 to node 154.

Controlled by the pMOS field effect transistor 147, the current between node 156 and node 155 is adjusted.

The voltage obtained by resistively dividing the voltage between terminals 201 and 202 is inverted and amplified a total of three times by nMOS inverter 108, pMOS inverter 109, and nMOS inverter 129 to control pMOS field effect transistor 125 and pMOS field effect transistor 126. The voltage obtained by resistively dividing the voltage between terminals 201 and 202 is inverted and amplified a total of three times by nMOS inverter 108, pMOS inverter 109, and nMOS inverter 149 to control pMOS field effect transistor 145 and pMOS field effect transistor 146.

The voltage obtained by resistively dividing the voltage between terminals 201 and 202 is inverted and amplified a total of two times by pMOS inverter 110 and nMOS inverter 130 to control pMOS field effect transistor 127. The voltage between terminals 201 and 202 is resistively divided and inverted and amplified twice in total by pMOS inverter 110 and nMOS inverter 150 to control pMOS field effect transistor 147.

When the voltage between terminals 201 and 202 is high, the input voltage to nMOS inverter 108 is high, the output voltage of nMOS inverter 108 is low, the voltage of pMOS inverter 109 is high, the output voltage of nMOS inverter 129 is low, and pMOS field effect transistor 125 and pMOS field effect transistor 126 are turned on. When the voltage between terminals 201 and 202 is low, the input voltage to nMOS inverter 108 is low, the output voltage of nMOS inverter 108 is high, the voltage of pMOS inverter 109 is low, the output voltage of nMOS inverter 129 is high, and pMOS field effect transistor 125 and pMOS field effect transistor 126 are turned off.

When the voltage between terminals 201 and 202 is high, the input voltage of nMOS inverter 108 is high, the output voltage of nMOS inverter 108 is low, the voltage of pMOS inverter 109 is high, the output voltage of nMOS inverter 149 is low, and the pMOS field effect transistor 145 and pMOS field effect transistor 146 are turned on. When the voltage between terminals 201 and 202 is low, the input voltage of nMOS inverter 108 is low, the output voltage of nMOS inverter 108 is high, the voltage of pMOS inverter 109 is low, the output voltage of nMOS inverter 149 is high, and the pMOS field effect transistor 145 and pMOS field effect transistor 146 are turned off.

When the voltage between terminals 201 and 202 is high, the input voltage of the pMOS inverter 110 becomes high, the output voltage of the pMOS inverter 110 becomes low, the output voltage of the nMOS inverter 130 becomes high, and the pMOS field effect transistor 127 is turned off. When the voltage between terminals 201 and 202 is low, the input voltage of the pMOS inverter 110 becomes low, the output voltage of the pMOS inverter 110 becomes high, the output voltage of the nMOS inverter 130 becomes low, and the pMOS field effect transistor 127 is turned on.

When the voltage between terminals 201 and 202 is high, the input voltage of the pMOS inverter 110 becomes high, the output voltage of the pMOS inverter 110 becomes low, and the output voltage of the nMOS inverter 150 becomes high, and the pMOS field effect transistor 147 is turned off. When the voltage between terminals 201 and 202 is low, the input voltage of the pMOS inverter 110 is low, the output voltage of the pMOS inverter 110 is high, and the output voltage of the nMOS inverter 130 is low, turning on the pMOS field effect transistor 127.

The voltage between terminals 201 and 202 at the boundary between whether the pMOS field effect transistor 125 and the pMOS field effect transistor 145 are turned on or off, which is determined according to the ratio of the resistance value of resistor 105 plus the resistance value of resistor 106 to the resistance value of resistor 107, is called the first constant voltage value. Similarly, the voltage between terminals 201 and 202 at the boundary between whether the pMOS field effect transistor 127 and the pMOS field effect transistor 147 are turned on or off, which is determined according to the ratio of the resistance value of resistor 105 to the resistance value of resistor 106 plus the resistance value of resistor 107, is called the second constant voltage value.

When the voltage between terminals 201 and 202 is greater than the first constant voltage value, the pMOS field effect transistor 125 and the pMOS field effect transistor 145 are turned on. When the voltage between terminals 201 and 202 is less than the first constant voltage value, the pMOS field effect transistor 125 and the pMOS field effect transistor 145 are turned off.

When the voltage between terminals 201 and 202 is greater than the second constant voltage value, the pMOS field effect transistor 127 and the pMOS field effect transistor 147 are turned off. When the voltage between terminals 201 and 202 is less than the second constant voltage value, the pMOS field effect transistor 127 and the pMOS field effect transistor 147 are turned on.

To operate the system of the present invention correctly, the second constant voltage value is made higher than the first constant voltage value. When the voltage between the terminals 201 and 202 is smaller than the first constant voltage value, the pMOS field effect transistor 125 and the pMOS field effect transistor 145 are turned off, and the pMOS field effect transistor 127 and the pMOS field effect transistor 147 are turned on. When the voltage between the terminals 201 and 202 is greater than the first constant voltage value and less than a second constant voltage value, the pMOS field effect transistor 125 and the pMOS field effect transistor 145 are turned on, and the pMOS field effect transistor 127 and the pMOS field effect transistor 147 are turned on. When the voltage between the terminals 201 and 202 is greater than a second constant voltage value, the pMOS field effect transistor 125 and the pMOS field effect transistor 145 are turned off, and the pMOS field effect transistor 127 and the pMOS field effect transistor 147 are turned on.

For example, the first voltage value is 16.5V, and the second constant voltage value is 17.0V. It is considered that the first voltage value a value is optimally set to about 0.5V lower than the voltage at which the maximum power can be extracted from the solar module is optimal. It is considered that the second voltage value is optimally set to about 1V lower than the voltage at which the maximum power can be extracted from the solar module, taking into account the wiring resistance. It is also considered that the first voltage value is optimally set to about 0.5V lower than the second constant voltage value, taking into account the static margin for stable operation of the computer (PC).

When the voltage between terminals 201 and 202 is near the first constant voltage value, the pMOS field effect transistor 125 and the pMOS field effect transistor 145 are in an intermediate state between on and off. The switching elements used in places such as 125 and 145 are suitable to have a completely off state, a completely on state, and an intermediate state between on and off.

When the voltage between terminals 201 and 202 is greater than the first constant voltage value, pMOS field effect transistor 125 and pMOS field effect transistor 145 are turned on, so the voltage from solar module 11 is converted by DC/DC converter 122 via terminal 201, and the current flowing through pMOS field effect transistor 125 increases. As a result, the potential between terminals 201 and 202 drops and becomes smaller than the first constant voltage value, so the voltage from solar module 11 is converted by DC/DC converter 122 via terminal 201, and the current flowing through pMOS field effect transistor 125 decreases. As a result, the potential between terminals 201 and 202 rises, resulting in a feedback such that the potential between terminals 201 and 202 becomes greater than the first constant voltage value.

When the voltage between terminals 201 and 202 is smaller than the second constant voltage value, pMOS field effect transistor 127 and pMOS field effect transistor 147 are turned on, and the current flowing through pMOS field effect transistor 127 increases. As a result, if the power consumed in the demand section of the computer (PC) is the same, the voltage is converted by DC-DC converter 122 from solar module 11 via terminal 201, and the current flowing through pMOS field effect transistor 125 decreases. As a result, the potential between terminals 201 and 202 rises and becomes larger than the second constant voltage value, and the current flowing through pMOS field effect transistor 127 decreases. As a result, if the power consumed in the demand section of the computer (PC) is the same, the voltage is converted by DC-DC converter 122 from solar module 11 via terminal 201, and the current flowing through pMOS field effect transistor 125 increases. As a result, the voltage between terminals 201 and 202 drops, becoming smaller than the second constant voltage value, resulting in feedback.

When the circuit of this embodiment is actually connected to a computer (PC) and operated, the following occurs.

When the solar module is not generating power, the voltage between terminals 201 and 202 becomes zero. When the computer (PC) is on, power is supplied from the commercial power supply 14 and computer (PC) power supply 13 to the CPU 15, motherboard 16, storage 17, and GPU, which are the power demand parts of the computer (PC). When the computer (PC) is off, only a constant power supply of 5V is supplied to the motherboard 16 from the commercial power supply 14 and computer (PC) power supply 13.

Even if the potentials of nodes 135 and 136 are about 12V at this time, the pMOS field effect transistor 126 stops the reverse current, so the current does not flow back from node 135 through the pMOS field effect transistor 126, pMOS field effect transistor 125, DC-DC converter 122, and terminal 201 to the solar module 11. Therefore, if there is only one solar module, a reverse current prevention diode is not necessary.

When the solar module is slightly exposed to the sun in the early morning or evening, the voltage between terminals 201 and 202 becomes equal to or lower than a first constant value. When the computer (PC) is on, power is supplied to the CPU 15, motherboard 16, storage 17, and GPU, which are the power demand parts of the computer (PC), from the commercial power supply 14 and power supply for computer (PC) 13. When the computer (PC) is off, only a constant power supply of 5V is supplied to the motherboard 16 from the commercial power supply 14 and the power supply for computer (PC) 13.

When the power generated by the solar module is less than the power consumed by the power demand parts of the computer (PC), the CPU 15, the motherboard 16, and the storage 17, which are 12V and normal 5V, the voltage between terminals 201 and 202 is balanced at a first constant voltage value, or at a second constant voltage value, or between the first constant voltage value and the second constant voltage value.

Whether the voltages are balanced at the first constant voltage value, at the second constant voltage value, or between the first and second constant voltage values is often determined by the magnitude relationship between the output of the DC-DC converter 122 and the 12V output of the power supply for computer (PC) 13, and the magnitude relationship between the output of the DC-DC converter 142 and the 5V output of the power supply for computer (PC) 13. Normally, the system of the present invention operates stably whether the voltages are balanced at the first constant voltage value, at the second constant voltage value, or between the first and second constant voltage values, so it doesn't matter which one it is.

For simplicity's sake, let's assume that there is only a 12V system.

When the output of the DC-DC converter 122 is greater than the 12V (actually, it is often a little higher than 12V) of the power supply for computer (PC) 13, the power supplied from the solar module 11 via the DC-DC converter 122 is used in preference to the power supplied from the 12V of the power supply for computer (PC) 13. Note that this can be said in terms of the magnitude of the supply voltage, but switching control is not taken into consideration. All the power supplied from the solar module 11 via the DC-DC converter 122 is used by the power demand section of the computer (PC), and only the shortage of power is supplied from the 12V of the power supply for computer (PC) 13. At that time, if the power supplied from the solar module 11 via the DC-DC converter 122 is greater than the power generated by the solar module 11, the pMOS field effect transistor 125 turns on, and the voltage between the terminals 201 and 202 drops and falls below the first constant voltage value. If the power supplied from the solar module 11 via the DC-DC converter 122 is less than the power generated by the solar module 11, the pMOS field effect transistor 125 turns off, and the voltage between the terminals 201 and 202 rises and exceeds the first constant voltage value. Therefore, the voltage between the terminals 201 and 202 becomes the first constant voltage value.

If the output of the DC-DC converter 122 is less than 12V (actually, it is often a little higher than 12V) of the power supply for computer (PC) 13, the power supplied from the 12V of the power supply for computer (PC) 13 is used in preference to the power supplied from the solar module 11 via the DC-DC converter 122. This can be said from the viewpoint of the magnitude of the supply voltage, but the control by switching control is not taken into consideration. At this time, when the voltage between terminals 201 and 202 is between the first constant voltage value and the second constant voltage value, power is supplied from the solar module 11 via the DC-DC converter 122, and also from the 12V of the power supply for computer (PC) 13. Therefore, during this time, the voltage between terminals 201 and 202 continues to rise. What happens if the voltage between terminals 201 and 202 becomes the second voltage value?

We are considering a case where the power generated by the solar module is smaller than the power consumed by the CPU 15, motherboard 16, and storage 17, which are the power demand parts of the computer (PC), which are 12V, normal 5V, so all the power supplied from the solar module 11 via the DC-DC converter 122 is used by the power demand parts of the computer (PC). As a result, when the voltage between the terminals 201 and 202 exceeds the second constant voltage value, the pMOS field effect transistor 127 is turned off, and the current supplied from the 12V power supply 13 for the computer (PC) is reduced. Therefore, the current supplied from the solar module 11 via the DC-DC converter 122 increases. As a result, the voltage between the terminals 201 and 202 drops and falls below the second constant voltage value. As a result, when the voltage between the terminals 201 and 202 falls below the second constant voltage value, the pMOS field effect transistor 127 is turned on, and the current supplied from the 12V power supply 13 for the computer (PC) is increased. Therefore, the current supplied from the solar module 11 via the DC-DC converter 122 is reduced. As a result, the voltage between the terminals 201 and 202 rises and exceeds the second constant voltage value. Therefore, the voltage between the terminals 201 and 202 becomes the second constant voltage value.

In addition, when the output of the DC-DC converter 122 and the 12V of the power supply for computer (PC) 13 are almost the same, the voltage between terminals 201 and 202 may be between the first constant voltage value and the second constant voltage value.

The above describes the case where there is only a 12V system. When a normal 5V system is added, it becomes more complicated, but the fact remains that the voltage between terminals 201 and 202 may be balanced at the first constant voltage value, the second constant voltage value, or between the first constant voltage value and the second constant voltage value.

Note that even in the same system, the voltage between terminals 201 and 202 may be balanced at the first constant voltage value, the second constant voltage value, or between the first constant voltage value, and the second constant voltage value.

As described above, when the power generated by the solar module is less than the power consumed by the power demand parts of the computer (PC), that is, the CPU 15, the motherboard 16, and the storage 17, which are 12V (normal 5V), the power supplied from the solar module 11 via the DC-DC converter 122 and the power supplied from the commercial power source 14 and the power source 13 for the computer (PC) are coordinated to supply power to the power demand parts of the computer (PC). The principle is feedback control. The power supplied from the solar module 11 via the DC-DC converter 122 is used preferentially, and only the part that is not enough is covered by the power supplied from the commercial power source 14 and the power source 13 for the computer (PC).

This is called coordinated power supply. With coordinated power supply, the power from the solar module 11 can be used effectively, even without a storage battery, as long as the power is used by the demand side of the solar module 11.

When the power generated by the solar module is greater than the power consumed by the 12V and normal 5V components of the power demand section of the computer (PC), that is, the CPU 15, motherboard 16, and storage 17, the voltage between terminals 201 and 202 becomes equal to or greater than a second constant voltage value. When the computer (PC) is on, power is supplied from the solar module 11 to the 12V and normal 5V components of the CPU 15, motherboard 16, storage 17, and GPU, that are the power demand sections of the computer (PC). When the computer (PC) is off, only the constant 5V power supply is supplied to the motherboard 16 from the commercial power supply 14 and computer (PC) power supply 13.

Next, the VDD power supply supplied to the nMOS inverter 108, pMOS inverter 109, pMOS inverter 110, nMOS inverter 129, nMOS inverter 130, nMOS inverter 149, and nMOS inverter 150 will be explained.

The VDD power supplies of the nMOS inverter 108, pMOS inverter 109, pMOS inverter 110, nMOS inverter 129, and nMOS inverter 130 are connected to node 137.

Node 137 is connected from node 134 via diode 124, and from node 136 via diode 128. Due to diodes 124 and 128, when at least one of node 134 and node 136 is about 12V, node 137 appears at a value close to 12V, or more precisely, a value obtained by subtracting the forward drop voltage of the diodes from 12V.

The VDD power supply of the nMOS inverter 149 and the nMOS inverter 150 is connected to the node 157.

The node 157 is connected from the node 154 via the diode 144, and from the node 156 via the diode 148. When at least one of the nodes 154 and 156 is about 5V, due to the diodes 144 and 148, the node 157 appears at a value close to 5V, or more precisely, a value obtained by subtracting the forward drop voltage of the diodes from 5V.

In this way, a stable VDD power supply of about 12V is supplied to the nMOS inverter 108, the pMOS inverter 109, the pMOS inverter 110, the nMOS inverter 129, and the nMOS inverter 130, and a stable VDD power supply of about 5V is supplied to the nMOS inverter 149 and the nMOS inverter 150.

In addition to the inverting and amplifying function, the nMOS inverter 149 and the nMOS inverter 150 also function as a 12V to 5V level shifter, and provide 5V L (low) and H (high) signals to the gates of the pMOS field effect transistor 145, the pMOS field effect transistor 146, and the pMOS field effect transistor 147.

The conditions necessary for the system of the present invention are explained below. The conditions necessary for the system of the present invention are:
1. To operate efficiently
2. To operate stably.

In order to operate efficiently, it is important that:
1A. The DC-DC converter 122 and the DC-DC converter 142 are efficient,
1B. In the circuit of FIG. 2, it is important to minimize the power consumption of the parts other than the DC-DC converter.

1A. Using efficient DC/DC converters 122 and 142 is a completely separate issue and a separate technology, and therefore this document will not discuss improving the efficiency of the DC/DC converters.

DC-DC converters are mounted on small circuit boards and are commercially available for a few thousand yen with a maximum output of 240 W and a maximum efficiency of 97%. Such highly efficient DC-DC converters can be used for DC-DC converter 122 and DC-DC converter 142.

1B. In the circuit of FIG. 2, in order to minimize the power consumption of parts other than the DC-DC converter, it is important to reduce the current consumption of the resistive voltage divider, each inverter, capacitor, etc.

When the resistive voltage divider 106-1 is set to, for example, a few kΩ in total, it operates stably and the current consumption is reduced. When the resistors in each inverter (resistors 401 and 404 in FIG. 5) are set to about 100 kΩ, it operates stably and the current consumption is reduced. The higher the resistance value of the resistors used, the less the power consumption, but the worse the stability. It is recommended to experiment to find the optimum resistance value. The optimum value varies depending on the application and the mounted components.

As for a capacitor, if the voltage applied to both ends is sufficiently lower than the withstand voltage of the capacitor, the leakage current is significantly suppressed. Therefore, the withstand voltage of the capacitor should be sufficiently high.

To operate stably, it is important to:
2A. Ensure a static margin
2B. Ensure a dynamic margin
2C. Connect a capacitor to each point.

Here, the static margin is defined as the difference between the voltage between the terminals 201 and 202 at which the pMOS field effect transistor 125 switches on and off, and the voltage between the terminals 201 and 202 at which the pMOS field effect transistor 127 switches on and off. In other words, it is the difference between the first constant voltage value and the second constant voltage value. The unit is V (volts). For example, 0.5 V is suitable for the static margin. While a larger static margin has the advantage of stable operation, it has the disadvantage that the voltage extracted from the solar module will deviate from the optimal condition, reducing the amount of power that can be extracted from the solar module.

A system with a static margin of about 0.5 to 0.6V was used as a normal computer (PC) use for two months and did not experience a single unintended power shutdown, unintended restart, or blue screen error, whereas a system with a static margin of less than 10 mV (millivolts) experienced an average of one unintended power shutdown, unintended restart, or blue screen error per day.

It is not easy to accurately determine how much static margin is necessary. However, the inventor believes that 0.5V is sufficient from the standpoint of reliability.

The voltage obtained by resistively dividing the voltage between terminals 201 and 202 is inverted and amplified three times by nMOS inverter 108, pMOS inverter 109, and nMOS inverter 129 to control pMOS field effect transistor 125 and pMOS field effect transistor 126. The voltage obtained by resistively dividing the voltage between terminals 201 and 202 is inverted and amplified three times by nMOS inverter 108, pMOS inverter 109, and nMOS inverter 149 to control pMOS field effect transistor 145 and pMOS field effect transistor 146.

The voltage obtained by resistively dividing the voltage between terminals 201 and 202 is inverted and amplified twice by pMOS inverter 110 and nMOS inverter 130 to control pMOS field effect transistor 127. The voltage between the terminals 201 and 202 is divided by resistors and inverted and amplified twice by the pMOS inverter 110 and the nMOS inverter 150 to control the pMOS field effect transistor 147.

By having two amplification systems in this way, it is possible to provide a difference between the first constant voltage value, which is the voltage between terminals 201 and 202 at the on/off boundary of the pMOS field effect transistor 125 and the pMOS field effect transistor 145, and the second constant voltage value, which is the voltage between terminals 201 and 202 at the on/off boundary of the pMOS field effect transistor 127 and the pMOS field effect transistor 147.

The resistance value of resistor 105 is, for example, 1500 Ω, the resistance value of resistor 106 is, for example, 1847 Ω, and the resistance value of resistor 107 is, for example, 300 Ω. Although it depends on the design of other parts and the selection of elements, in this case, for example, the first constant voltage value is about 16.5 V and the second constant voltage value is about 17.0 V.

Next, dynamic margin will be described. When the voltage between terminals 201 and 202 changes from a high voltage to a low voltage in a short time, the pMOS field effect transistor 125 changes from on to off, and the pMOS field effect transistor 127 changes from off to on. When the voltage between terminals 201 and 202 changes from a low voltage to a high voltage in a short time, the pMOS field effect transistor 125 changes from off to on, and the pMOS field effect transistor 127 changes from on to off.

The difference in time between the time when the pMOS field effect transistor 125 changes from on to off and the time when the pMOS field effect transistor 127 changes from off to on, the time when the pMOS field effect transistor 125 changes from off to on and the time when the pMOS field effect transistor 127 changes from on to off are defined to be dynamic margins.

Ensuring a dynamic margin means making a difference between the time when the pMOS field effect transistor 125 changes from on to off and the time when the pMOS field effect transistor 127 changes from off to on, and between the time when the pMOS field effect transistor 125 changes from off to on and the time when the pMOS field effect transistor 127 changes from on to off.

One method for doing this is to make a difference in the time when the switching element to be controlled changes between on and off after the voltage between the terminals 201 and 202 changes from a small voltage to a large voltage in a short time, and the time when the switching element to be controlled changes between on and off after the voltage between the terminals 201 and 202 changes from a large voltage to a small voltage in a short time, for each system.

To do this, it is recommended that the final stage of the amplification system be an nMOS inverter as shown in FIG. 5(a). In an nMOS inverter as shown in FIG. 5(a), when the input changes from L (low) to H (high), the potential of the output node drops sharply via the nMOS field effect transistor 402. Therefore, the speed at which the output changes from H (high) to L (low) is fast. Therefore, for example, the speed at which the pMOS field effect transistor 125 changes from off to on is fast.

When the input changes from H (high) to L (low), the potential of the output node rises slowly via the resistor 401. Therefore, the speed at which the output changes from L (low) to H (high) is slow. Therefore, for example, the speed at which the pMOS field effect transistor 125 changes from on to off is slow.

Here, in order to slow down the speed at which the output changes from L (low) to H (high) in FIG. 5(a), it is necessary that a capacitance is connected to the output part of FIG. 5(a). To do this, there is a method of connecting a capacitor. However, it is possible to add a capacitance component without intentionally connecting a capacitor. Normally, the pMOS field effect transistor 125 and the pMOS field effect transistor 126 handle a large current, so the parasitic capacitance of the gate is large. For example, a parasitic capacitance of about 0.1 μF (microfarad) is generated.

Therefore, this parasitic capacitance and the resistance value of the resistor 401 form a CR time constant. If the parasitic capacitance of the pMOS field effect transistor 125 and the pMOS field effect transistor 126 is 0.1 μF (microfarad) and the resistance value of the resistor 401 is 100 kΩ (kiloohms), the time constant of the speed at which the output changes from L (low) to H (high) in FIG. 5(a) is about 10 ms (milliseconds). On the other hand, the on-resistance of the nMOS field effect transistor 402 is much smaller than 100 kΩ (kiloohms), so the time constant of the speed at which the output changes from H (high) to L (low) in FIG. 5(a) is much smaller than 10 ms (milliseconds).

In this way, the speed at which the pMOS field effect transistor 125 changes from on to off can be made much slower than the speed at which the pMOS field effect transistor 125 changes from off to on. At least, the difference between the two can be made by two to three orders of magnitude or more.

The pMOS field effect transistor 125, pMOS field effect transistor 127, pMOS field effect transistor 145, and pMOS field effect transistor 147 can change from on to off much slower than the speed at which they change from off to on.

The nMOS inverter 129 and nMOS inverter 130 have the following two roles:
Inversion amplification
Delay function from L (low) to H (high)

The nMOS inverter 149 and nMOS inverter 150 have the following three roles:
Inverting amplification
Level shifting
Low to high delay function

By doing as described above, it is possible to differentiate the time when the switching element to be controlled changes on/off after the voltage between terminals 201 and 202 changes from a small voltage to a large voltage in a short time, and the time when the switching element to be controlled changes on/off after the voltage between terminals 201 and 202 changes from a large voltage to a small voltage in a short time, and to ensure a dynamic margin.

In addition, stable operation was confirmed when the resistance value of resistor 401 was 100 kΩ. The higher this resistance value, the less wasted power is, and the greater the difference between the time when the switching element changes from on to off and the time when the switching element changes from off to on can be achieved. However, if the resistance value of resistor 401 is increased to about 1 MΩ, the power from the solar module is stopped too late even when it should be stopped, and even when output from the power source for the computer (PC) is required, the power source for the computer (PC) may determine that there is no need to supply power, and the power source for the computer (PC) may not supply power. In this case, the power supply from the solar module stops after a long time has passed, and power is not supplied from either the solar module or the power source for the computer (PC), causing the computer (PC) to shut down. Therefore, the resistance value of resistor 401 cannot be too high. It is considered that accurate optimization of the resistance value of resistor 401 is included in the design matters.

By ensuring a static margin and a dynamic margin, the computer (PC) can be operated stably regardless of the power generation status of the solar module or the power consumption of the power demand section of the computer (PC). In the inventor's experiment, this system was introduced and there were no unintended shutdowns, restarts, or blue screen errors for two months.

Finally, we will explain how to connect capacitors to each location. Incidentally, connecting capacitors can also be thought of as part of ensuring a dynamic margin. Normally, capacitors are attached to the input and output of a DC-DC converter. This is because the DC-DC converter will not operate correctly if this is not done. The capacitors used for this purpose are 121, 141, 123, and 143. In addition to these minimum capacitors, there are also provided large-capacity capacitor 101 for stabilizing the input of coordinated power supply, capacitor 131 for stabilizing the VDD power supplied to nMOS inverter 108, pMOS inverter 109, pMOS inverter 110, nMOS inverter 129, and nMOS inverter 130, capacitor 151 for stabilizing the VDD power supplied to nMOS inverter 149 and nMOS inverter 150, capacitors 133 and 153 for stable operation when power from the power supply for computer (PC) is suddenly required, and capacitors 132 and 152 for when power generated by coordinated power supply is suddenly required by the power demand section.

For example, a large-capacity capacitor of about 10,000 μF (microfarads) is suitable for stabilizing the input of coordinated power supply. If a capacitance of this magnitude is connected, even if the wiring from the solar module 11 is cut off for some reason, the computer (PC) will continue to operate by switching to power supply only from the power supply for computer (PC). Also, although it may work without such a large-capacity capacitor, if the voltage between terminals 201 and 202 changes suddenly, coordinated power supply will not work even if dynamic margins are taken into account, and the computer (PC) may shut down. Therefore, a large-capacity capacitor 101 is necessary for coordinated power supply.

In addition, it is better to have capacitors 121 and 141 located immediately next to the DC-DC converter input. Capacitors 121 and 141 have smaller capacitance than capacitor 101, and a combination of an electrolytic capacitor and a ceramic capacitor is preferable. Capacitors 123 and 143 are also preferably a combination of an electrolytic capacitor and a ceramic capacitor.

It would be better to have a capacitor 131 for stabilizing the VDD power supplied to the nMOS inverter 108, the pMOS inverter 109, the pMOS inverter 110, the nMOS inverter 129, and the nMOS inverter 130, and a capacitor 151 for stabilizing the VDD power supplied to the nMOS inverter 149 and the nMOS inverter 150.

Capacitors 133 and 153 should be provided for stable operation when power from the power supply for computer (PC) is suddenly required, and capacitors 132 and 152 should be provided for when the power generated by the coordinated power supply is suddenly required by the power demand section.

However, it is possible for the system to operate without capacitors 131, 151, 132, 152, 133, and 153, and they are provided to further increase stability and reliability. It is considered a design matter to accurately determine the capacitance of each capacitor. However, it is considered that making the capacitor 101 have a sufficiently large capacity can constitute part of the patentability.

As described above, by ensuring a static margin and a dynamic margin, stable operation is achieved. By connecting capacitors to each location, operation becomes even more stable.

Next, we will discuss the power linkage with the computer (PC). What would happen if power continued to be supplied to terminals 206 and 210 even after the computer (PC) was turned off? In that case, the power supply fan would continue to run even after the computer (PC) was turned off. This is sure to bother many people. Not only that, but if power continues to be supplied to terminals 206 and 210 even after the computer (PC) was turned off, the computer (PC) may not turn on even if you try to turn it on afterwards. However, this may differ depending on the computer (PC). Therefore, when the computer (PC) is turned off, power should not be supplied to terminals 206 and 210.

To achieve this, the inventor drops the node between resistors 105 and 106 to 0V when a signal to turn off the power supply of the computer (PC) is received, turns off the pMOS field effect transistor 125 and the pMOS field effect transistor 145, and prevents power from being supplied from the solar module 11 to the power demanding parts of the computer (PC), namely the CPU 15, the motherboard 16, the storage 17, and the GPU 18. When the power supply of the computer (PC) is turned off, H (high) is supplied to the terminal 203, and this signal can be used.

When H (high) is supplied to the terminal 203, the nMOS field effect transistor 104 turns on after a certain period of time has passed. Therefore, regardless of the voltage between the terminals 201 and 202, the node between resistors 105 and 106 and the node between resistors 106 and 107 will be at a voltage almost equal to GND, that is, close to 0V. As a result, the signal is inverted and amplified a total of three times by the nMOS inverter 108, the pMOS inverter 109, and the nMOS inverter 129, and H (high) is input to the pMOS field effect transistor 125 and the pMOS field effect transistor 126, which turn off the pMOS field effect transistor 125 and the pMOS field effect transistor 126. The signal is inverted and amplified a total of three times by the nMOS inverter 108, the pMOS inverter 109, and the nMOS inverter 149, and H (high) is input to the pMOS field effect transistor 145 and the pMOS field effect transistor 146, which turn off the pMOS field effect transistor 145 and the pMOS field effect transistor 146.

By the same token, the pMOS field effect transistor 127 and the pMOS field effect transistor 147 turn on. However, if the power supply for computer (PC) is off, no power is supplied from the power supply for computer (PC) 13. Since no power is supplied from the solar module 11, no power is supplied to the power demand parts of the computer (PC), namely the CPU 15, motherboard 16, storage 17, and GPU 18.

On the other hand, when L (low) is supplied to terminal 203, power is supplied from the power supply for computer (PC) 13, coordinated power supply from the solar module 11 and the power supply for computer (PC) 13, and power supply from the solar module 11 is performed according to the voltage between terminals 201 and 202, and power is supplied to the power demand parts, namely the CPU 15, motherboard 16, storage 17, and GPU 18.

Next, the delay circuit 102-1 will be described. The delay circuit 102-1 includes a resistor 102 and a capacitor 103, and operates with a CR time constant. For example, when the resistance value of resistor 102 is 100 kΩ (kiloohms) and the capacitance of capacitor 103 is 47 μF (microfarads), the CR time constant is 4.7 seconds. When the power supply of the computer (PC) is turned off and the potential of terminal 203 becomes H (high), the voltage between resistors 105 and 106 becomes 0 V after 3 to 5 seconds, which is the same order of time as the CR time constant. When the power supply of the computer (PC) is turned on and the potential of terminal 203 becomes L (low), the voltage between resistors 105 and 106 becomes the potential resulting from the voltage divided between terminals 201 and 202 after 3 to 5 seconds, which is the same order of time as the CR time constant.

Let us consider the effect of using a delay circuit in this way. When a signal to turn off the power supply to the computer (PC) is received, the power supply from the power supply 13 for the computer (PC) should be turned off. However, what happens if the power from the solar module 11 is cut off before the power supply from the power supply 13 for the computer (PC) is turned off? In this case, the power required by the power supply 13 for the computer (PC) suddenly increases, and since it appears from the perspective of the power supply 13 for the computer (PC) that a large amount of power has been suddenly required, the computer may decide that it is not appropriate to turn off the power.

When a signal to turn on the power supply to the computer (PC) is received, the power supply from the power supply 13 for the computer (PC) should be turned on. However, what happens if a sudden increase in power is supplied from the solar module 11 before the power supply from the power supply 13 for the computer (PC) is turned on? In this case, the power required by the power supply for computer (PC) 13 suddenly decreases, and the power supply for computer (PC) 13 may decide that it does not need to supply power because it suddenly no longer needs power, and may stop supplying power. There are cases where the power from the solar module 11 can cover all of the power of the 12V system, normal 5V system, but even in that case, the power supply for computer (PC) 13 needs to be prepared to supply power at any time in case of a sudden increase in power demand.

In this situation, when a signal to turn the power supply for computer (PC) on and off is received, it is good to use a delay circuit to switch whether or not to supply power from the solar module 11 to the power demand section after a certain time has elapsed.

FIG. 8 shows the relationship between the voltage at both ends of the solar module, the current that can be extracted, and the power that can be extracted. FIG. 8 shows an example for a 12V system.

When the voltage at both ends of the solar module is 0V, the maximum current flows. This current is called short-circuit current. The current that flows remains almost constant until the voltage across the solar module reaches approximately 17V, at which point the voltage across the solar module decreases from approximately 17V, and the current that flows becomes zero when the voltage across the solar module increases to a certain extent. The voltage at which the current flows becomes zero is called open voltage.

When the voltage across the solar module is 0V, the power that can be extracted is zero. When the voltage across the solar module is, for example, approximately 17.5V, the power that can be extracted is maximized, and the power that can be extracted at the release voltage is zero. Taking into account the wiring resistance, the maximum power can be extracted in an actual system with wiring resistance when the power is extracted at approximately 17V, which is slightly lower than 17.5V at which the maximum power can be extracted when only the solar module is considered. In the circuit of FIG. 6, if the resistance values of resistors 105, 106, and 107 are adjusted so that pMOS field effect transistor 125 and pMOS field effect transistor 127 switch when the output voltage of solar module 511 is approximately 17V, a large amount of power can be extracted.

At night, the solar module 11 does not generate power, and the output of the solar module 11 becomes zero. At that time, the input of the inverter 108 becomes L (low), the output of the inverter 108 becomes H (high), the output of the inverter 109 becomes L (low), and the output of the inverter 129 becomes H (high). As a result, the pMOS field effect transistor 126 turns off, and the pMOS field effect transistor 127 turns on. If the switching element is configured with two pMOS field effect transistors connected in series with their sources facing in the opposite direction, when the pMOS field effect transistor 126 is off, no current flows from right to left through the pMOS field effect transistor 126 in FIG. 2. Therefore, if the solar module 11 is configured with one module, a reverse current prevention diode is not necessary. If there is a reverse current prevention diode, the forward voltage drops by about 0.4 V to 1.0 V. Therefore, the absence of a reverse current prevention diode contributes to improving the power efficiency of the system.

Unlike normal independent power systems, the system shown in FIG. 2 can operate without a 12V lead-acid battery. Therefore, there is no need for depreciation costs for lead-acid batteries. This allows for low maintenance costs. The part in FIG. 2 may be used in combination with a PC (computer) power supply, or may be integrated with the PC (computer) power supply. When used in combination with a PC (computer) power supply, the PC (computer) power supply can be an ATX power supply or the like that is common in 2025.

So, we experimented to see how much effective efficiency we could get with this system. For the experiment, we used a computer (PC) equipped with an Intel (company name) CPU, Core i5-13500 (product name), and without a dedicated graphics board. The experiment was conducted by running the benchmark test program for the game Uncharted Waters Online (product name) by Koei Tecmo Co., Ltd. (company name), the Uncharted Waters Online Benchmark, for 168 hours each time. The first time, no power was supplied from the simulated sunlight, and the other time, a maximum of 19V and 2 A of power was supplied as simulated sunlight, the difference was calculated, and the cumulative power supplied was also measured. The power consumed by the computer (PC) at 12V, normal 5V, was set to be sufficiently greater than the power supplied from the simulated sunlight.

As a result, when no power of simulated sunlight was supplied, the power was 98.15 W, and when power of simulated sunlight was supplied, it was 65.24 W. The difference was 32.91 W. The cumulative power supplied was 31.96 W. As a result, 32.91 W/31.96 W=103%. The effective efficiency, defined as the power saved from commercial power/power supplied from the simulated sunlight, was 103%.

This effective efficiency of 103% does not mean that the conversion efficiency of the DC-DC converter is 103%. This is because the definition of effective efficiency is not the definition of the conversion efficiency of the DC-DC converter itself. However, since this effective efficiency is the power that can be saved from the commercial power source/the power supplied from the simulated sunlight, this effective efficiency can exceed 100%. This result means that it is possible to save more power from the commercial power source than the power supplied from the solar panel.

The essential reason why this is possible is that while the power from the commercial power source is converted once by AC-DC conversion, the power from the solar module is also converted once by the DC-DC converter. Therefore, if the efficiency of the DC-DC conversion from the solar module is higher than the efficiency of the AC-DC conversion of the commercial power source, the effective efficiency defined as the power that can be saved from the commercial power source/the power supplied from the simulated sunlight can exceed 100%. In reality, the main circuit 12 itself consumes power, and the efficiency is, for example, about 2% lower than the difference between the AC/DC conversion efficiency of the commercial power supply and the DC/DC conversion efficiency from the solar module. However, if the DC/DC conversion efficiency from the solar module is sufficiently higher than the AC/DC conversion efficiency from the commercial power supply, it may still exceed 100%.

To give an image of the efficiency, a specific example will be given. Assume that the AC/DC conversion efficiency of the commercial power supply is 88% and the DC/DC conversion efficiency is 92%, that 30 W is supplied from the solar module, and that the main circuit 12 itself does not consume power. In this case, if the power that can be saved by the solar module out of the power supplied from the commercial power supply to 12 V and normal 5 V is X, the power that can be saved by the solar module out of the power supplied to 12 V and normal 5 V in the power demand section is X×0.88. On the other hand, the power supplied from the solar module to 12 V and normal 5 V in the power demand section is 30 (W)×0.92. Since both companies are the same, X×0.88=30 (W)×0.92. X=30 (W)×0.92/0.88, so X exceeds 30 (W). X/30 (W)=0.92/0.88.

Note that this experiment is costly and cannot be repeated. Therefore, the first experiment was conducted only once when the simulated sunlight power supply was not used, and the second experiment was conducted only once when the maximum of 19V and 2 A of power was used as the simulated sunlight power supply. Ideally, a computer (PC) should consume a constant amount of power, but even if the same benchmark program is running, there is some variation in power consumption, which can result in dispersion. Therefore, the effective efficiency, defined as the power saved from commercial power supply/power supplied from simulated sunlight, may not be 103%, and may even be less than 100%. However, in principle, it may exceed 100%. In this way, the effective efficiency, defined as the power saved from commercial power/power supplied from simulated sunlight, can exceed 100%.

From here, we will explain related technologies. FIG. 3 shows an example of the inside of a DC-DC converter. There are insulated and non-insulated DC-DC converters. Non-insulated DC-DC converters are step-up and step-down. A non-insulated step-down type is suitable for converting the voltage of about 17V from a solar module to 12V or 5V. The example shown in FIG. 3 is an example of a non-insulated step-down DC-DC converter.

The principle will be briefly explained. When the switching element is turned on by the output L (low) of the controller 202, a current flows from the input to the output via the switching element 201 and the inductor 204. When the switching element 201 is turned off by the output H (high) of the controller 202, a current flows from VSS to the output via the diode 203 and the inductor 204.

Sin there is a current flowing from VSS via the diode 203 and inductor 204, in the case of a step-down type, the current is greater at the output than at the input, but the voltage at the output is smaller than at the input.

Since the controller 202 turns the switching element 201 on and off at several hundred kHz (kilohertz), the inductor 204 can be small, and the capacitors 123 and 143 connected to the output do not need to have a large capacity. This allows the DC-DC converter to be small.

In addition to the capacitors 123 and 143 connected to the output side, the capacitors 121 and 141 are also connected to the input side. Usually, both an electrolytic capacitor and a ceramic capacitor are required on the input side, and an electrolytic capacitor is required on the output side. The ceramic capacitor may be integrated with the DC-DC converter.

The voltage obtained by dividing the output voltage by resistors 205 and 206 is input to the controller and fed back. Usually, the output voltage can be set by adjusting the resistance value of one or both of resistors 205 and 206. The resistance value of one or both of resistors 205 and 206 is designed according to the specifications of the DC-DC converter.

The DC-DC converter 122 outputs 12v, and the DC-DC converter 142 Outputs 5V. Because the output voltages are different, the resistance ratio of resistor 205 and resistor 206 in the DC-DC converter 122 is set to be different from the resistance ratio of resistor 205 and resistor 206 in the DC-DC converter 142.

FIG. 4 is an example of a circuit diagram inside a power supply for computer (PC). The power supply for computer (PC) rectifies the input by a full-wave rectifier consisting of diodes 301, 302, 303, 304, and capacitor 305.

Then, the voltage is stepped down by transformer 307, switching element 312, controller 308, diode 306, and capacitor 309. A signal controlled by the controller 308 turns the switching element 312 on and off, changing the current on the primary side. The current that appears on the secondary side is rectified by the diode 306, and only a forward current of the diode 306 appears. It is then smoothed by the capacitor 309. In this way, a voltage lower than the primary side appears on the secondary side. Normally, a current larger than that on the primary side is generated on the secondary side. As a result, 12V appears between the terminals 207 and 206.

The DC-DC converter 310 causes 5V to appear between the terminals 207 and 210. The DC-DC converter 311 causes 3.3V to appear. In this example, 5V and 3.3V are generated from 12V. However, 5V and 3.3V may also be generated directly from the primary side.

FIG. 5 is a circuit diagram of an inverter. FIG. 5(a) is a circuit diagram of an nMOS inverter circuit. The output is inverted relative to the input. That is, if the input is H (high), the output becomes L (low), and if the input is L (low), the output becomes H (high). The output changes from H (high) to L (low) quickly, and from L (low) to H (high) slowly. When the output changes from L (low) to H (high), the product of the capacitance connected to the output and the resistance of resistor 401 becomes the CR time constant.

FIG. 5(b) is a circuit diagram of a pMOS inverter circuit. The output is inverted with respect to the input. That is, if the input is H (high), the output becomes L (low), and if the input is L (low), the output becomes H (high). The output changes from H (high) to L (low) slowly, and from L (low) to H (high) quickly. When the output changes from H (high) to L (low), the product of the capacitance connected to the output and the resistance of resistor 404 becomes the CR time constant.

Further explanation of each elemental technology. FIG. 6 is a simple example of coordinated power supply. Coordinated power supply was explained in FIG. 2, but in FIG. 6, a simpler example of coordinated power supply is explained. In FIG. 6, the power from the solar module is converted to 5V and charged via USB. This example is given because there are experimental results that actually obtained the characteristics of coordinated power supply. FIG. 9 shows the same circuit as FIG. 2, but in a more simplified form. Although FIG. 2 accurately describes the details, the essence is difficult to see because of the details. FIG. 9 is described for the purpose of helping understanding rather than a detailed description.

FIG. 6 is a simple example of coordinated power supply. Power from the solar module 511 is converted to 5V by the DC-DC converter 503. Commercial AC power 509 is converted to 5V by the AC adapter 508. The 5V originating from the solar module 511 and the 5V originating from the commercial AC power are mixed via the switching element 504 and the switching element 505, and output to the smartphone 510 to be charged.

The output voltage of solar module 511 is resistively divided by resistors 501 and 502, inverted and amplified by inverter 506, and controls switching element 504. It is also input to inverter 507, where it is further inverted and amplified to control switching element 505.

When the output voltage of solar module 511 rises, the input to inverter 506 rises, the output of inverter 506 falls, and the output of inverter 507 rises. As a result, switching element 504 turns on and switching element 505 turns off. As a result, the power required by smartphone 510 to be charged is supplied more from the power originating from solar module 511 and less from the power originating from commercial AC power 509. As a result, the output voltage of solar module 511 falls.

When the output voltage of the solar module 511 drops, the input to the inverter 506 drops, the output of the inverter 506 rises, and the output of the inverter 507 drops. As a result, the switching element 504 turns off and the switching element 505 turns on. As a result, the power required by the smartphone 510 to be charged is supplied less from the power originating from the solar module 511 and more from the power originating from the commercial AC power 509. As a result, the output voltage of the solar module 511 rises.

This feedback allows the power originating from the solar module 511 and the commercial AC power 509 to be supplied to the smartphone 510, to be charged with an appropriate power distribution. When the power originating from the solar module 511 increases, the power originating from the commercial AC power 509 decreases, and when the power originating from the solar module 511 decreases, the power originating from the commercial AC power 509 increases.

Coordinated power supply is a technology that combines power from solar modules and commercial AC power,
based on feedback control,
and gives priority to using power from solar modules, and uses commercial AC power only when there is a shortage.

FIG. 7 shows the relationship between the current generated by the solar module 511, the pseudo solar output current, and the AC adapter output current. The pseudo solar output current is the current that flows through the switching element 504, and the AC adapter output current is the current that flows through the switching element 505. It is important to note that the power generated by the solar module 511 is the current in a 12V system, and the pseudo solar output current and the AC adapter output current are the current in a 5V system. In this way, the more the power generated by the solar module 511 increases, the more the pseudo solar output current increases and the AC adapter output current decreases. The more the power generated by the solar module 511 decreases, the more the pseudo solar output current decreases and the AC adapter output current increases.

FIG. 8 shows the relationship between the voltage across the solar module, the current that can be extracted, and the power that can be extracted. FIG. 8 shows an example for a 12V system.

When the voltage across the solar module is 0V, the maximum current flows. This current is called the short-circuit current. The current that flows remains almost constant until the voltage across the solar module reaches approximately 17V, at which point the voltage across the solar module decreases from approximately 17V, and when the voltage across the solar module increases to a certain extent, the current that flows becomes zero. The voltage at which the current flows becomes zero is called the open voltage.

When the voltage across the solar module is 0V, the power that can be extracted is zero. When the voltage across the solar module is, for example, approximately 17.5V, the power that can be extracted is maximized, and the power that can be extracted at the open voltage is zero. Taking into account the wiring resistance, the maximum power can usually be extracted by extracting power at approximately 17V, which is slightly lower than 17.5V, at which the maximum power can be extracted when only the solar module is considered. In the circuit of FIG. 6, if the resistance values of resistors 501 and 502 are adjusted so that switching elements 504 and 505 are switched on and off when the output voltage of solar module 511 is around 17V, a large amount of power can be extracted.

At night, solar module 511 does not generate power, and the output of solar module 511 becomes zero. At that time, the input of inverter 506 becomes L (low), the output of inverter 506 becomes H (high), and the output of inverter 507 becomes L (low). As a result, switching sled 504 turns off and switching element 505 turns on. If the switching element is configured as two pMOS field effect transistors connected in series with their sources facing in opposite directions, when switching sled 504 is off, no current flows from right to left through switching element 504 in FIG. 6. Therefore, if solar module 511 is configured as a single module, a reverse current prevention diode is not required. If a reverse current prevention diode is present, the forward voltage drops by about 0.4V to 1.0V. Therefore, the absence of a reverse current prevention diode contributes to improving the power efficiency of the system.

Unlike a normal independent power supply system, a system like that shown in FIG. 6 can operate without a 12V lead-acid battery. Therefore, there is no need for depreciation costs for lead-acid batteries. This makes it possible to keep maintenance costs low.

FIG. 9 shows the same circuit as in FIG. 2, but in a more simplified form. Power from the solar module 11 is converted to 12V by a DC-DC converter 122. Commercial AC power 14 is converted to 12V by a computer (PC) power supply 13. The 12V originating from the solar module 11 and the 12V originating from the commercial AC power are mixed via switching element 125-1 and switching element 127, and output to the power demand section of the computer (PC).

The output voltage of the solar module 11 is resistively divided by resistors 105, 106 and 107, inverted and amplified in three stages by inverters 108, 109, and 129, and controls the switching element 125-1. The output voltage of the solar module 511 is resistively divided by resistors 105, 106 and 107, inverted and amplified in two stages by inverters 110 and 130, and controls the switching element 127.

When the output voltage of the solar module 11 rises, the input of the inverter 108 rises, the output of the inverter 108 falls, the output of the inverter 109 rises, and the output of the inverter 129 falls. When the output voltage of the solar module 11 rises, the input of the inverter 110 rises, the output of the inverter 110 falls, and the output of the inverter 130 rises. As a result, the switching element 125-1 turns on and the switching element 127 turns off. As a result, the power required by the power demand section is supplied more from the power originating from the solar module 11 and less from the power originating from the commercial AC power 14. As a result, the output voltage of the solar module 11 drops.

When the output voltage of the solar module 11 drops, the input to the inverter 108 drops, the output of the inverter 108 rises, the output of the inverter 109 drops, and the output of the inverter 129 rises. Also, when the output voltage of the solar module 11 drops, the input to the inverter 110 drops, the output of the inverter 110 rises, and the output of the inverter 130 drops. As a result, the switching element 125-1 turns off and the switching element 127 turns on. As a result, the power required by the power demand section is supplied less from the power originating from the solar module 11 and more from the power originating from the commercial AC power 14. As a result, the output voltage of the solar module 11 rises.

By this feedback, the power demand section is supplied with an appropriate power distribution from the power originating from the solar module 11 and the power originating from the commercial AC power 14. When the power originating from the solar module 11 increases, the power originating from the commercial AC power 14 decreases, and when the power originating from the solar module 11 decreases, the power originating from the commercial AC power 14 increases.

As in the case of FIG. 6, by setting the switching element 125-1 and the switching element 127 to turn on and off at a voltage slightly lower than the voltage at which the maximum power can be extracted from the solar module itself, a large amount of power can be extracted from the solar module, and due to the characteristics of the control circuit, a reverse current prevention diode is not required when there is only one solar module. FIGS. 6 and 9 are drawings for understanding, so FIG. 2 should be mainly used for interpreting the claims.

FIG. 10 (circuit A), 11 (circuit I), 12 (circuit U), 13 (circuit E), 14 (circuit O), and 15 (circuit Ka) show the results of simulations performed with various circuit configurations and static margins and dynamic margins examined. As already mentioned, it is important to secure sufficient static and dynamic margins for stable operation of a computer. (a) is the circuit diagram used in the simulation, (b) is the static characteristics of the 12V system, (c) is the static characteristics of the 5V system, (d) is the dynamic characteristics of the 12V system, and (e) is the dynamic characteristics of the 5V system. Note that the explanation will be given using the corresponding components in FIG. 2.

FIG. 10 (circuit A), FIG. 11 (circuit I), and FIG. 12 (circuit U) show cases where the amplifier stage is separate in the amplifier series that controls switching elements 125, 126, and 127, while FIG. 13 (circuit E), FIG. 14 (circuit O), and FIG. 15 (circuit Ka) show cases where the amplifier stage is shared by the amplifier series of two switching elements. FIG. 10 (circuit A) and FIG. 13 (circuit E) show the case where the final stage of each amplification series is an nMOS inverter, FIG. 11 (circuit I) and FIG. 14 (circuit O) show the case where the final stage of each amplification series is a CMOS inverter, FIG. 12 (circuit U) and FIG. 15 (circuit Ka) show the case where the final stage of each amplification series is a pMOS inverter. FIG. 10 (circuit A) shows the configuration adopted in FIG. 2.

First, let us look at the static margin. In FIGS. 10, 11, 12, 13, 14, and 15 (b) and (c), the vertical axis represents the source-gate voltage of pMOS field effect transistor 125. In the FIGS. 10, 11, 12, 13, 14, and 15 (b) and (c), when the voltage is large, the pMOS field effect transistor 125 and the pMOS field effect transistor 127 turn on. A large static margin means that the input voltage range (output voltage of the solar module 511) at which both the pMOS field effect transistor 125 and the pMOS field effect transistor 127 turn on is large. A sufficient static margin means that the input voltage range (output voltage of the solar module 11) at which both the pMOS field effect transistor 125 and the pMOS field effect transistor 127 turn on is large is sufficient.

The condition for pMOS field effect transistor 125 and pMOS field effect transistor 127 to turn on is that the source-gate voltage is equal to or higher than a threshold, for example, 3V or higher. Looking at FIG. 10(b) and (c), when the input voltage, i.e., the voltage between terminals 201 and 202 in FIG. 2, is small and falls below a first constant voltage value, the 12V control PV side, i.e., pMOS field effect transistor 125, turns off, and the 12V control power supply for computer (PC) side, i.e., pMOS field effect transistor 127, turns on. When the input voltage, i.e., the voltage between terminals 201 and 202 in FIG. 2, when the voltage across terminal 202 rises and is between the first constant voltage value and the second constant voltage value, the 12V control PV side, i.e., pMOS field effect transistor 125, turns on, and the 12V control power supply for computer (PC) side, i.e., pMOS field effect transistor 127, turns on. When the input voltage, i.e., the voltage across terminals 201 and 202 in FIG. 2, further rises and exceeds the second constant voltage value, the 12V control PV side, i.e., pMOS field effect transistor 125, turns on, and the 12V control computer (PC) power supply side, i.e., pMOS field effect transistor 127, turns off. In the case of FIG. 10, a static margin is ensured.

Looking at FIG. 11(b) and (c), when the input voltage, i.e., the voltage between terminals 201 and 202 in FIG. 2, is small and falls below the first constant voltage value, the 12V control PV side, i.e., pMOS field effect transistor 125 is turned off, and the 12V control power supply for computer (PC) side, i.e., pMOS field effect transistor 127 is turned on. When the input voltage, i.e., the voltage between terminals 201 and 202 in FIG. 2, rises and is between the first constant voltage value and the second constant voltage value, the 12V control PV side, i.e., pMOS field effect transistor 125 is turned on, and the 12V control power supply for computer (PC) side, i.e., pMOS field effect transistor 127 is turned on. When the input voltage, i.e., the voltage between terminals 201 and 202 in FIG. 2, rises further and exceeds a second constant voltage value, the 12V control PV side, i.e., pMOS field effect transistor 125 turns on, and the 12V control computer (PC) power supply side, i.e., pMOS field effect transistor 127 turns off. In the case of FIG. 11, the line on the 12V control power supply for computer (PC) side changes gently, but a certain degree of static margin is secured.

Looking at FIG. 12(b) and (c), when the input voltage, i.e., the voltage between terminals 201 and 202 in FIG. 2, is small and falls below the first constant voltage value, the 12V control PV side, i.e., pMOS field effect transistor 125 turns off, and the 12V control computer (PC) power supply side, i.e., pMOS field effect transistor 127 turns on. When the input voltage, i.e., the voltage between terminals 201 and 202 in FIG. 2, rises and is between the first constant voltage value and the second constant voltage value, the 12V control PV side, i.e., pMOS field effect transistor 125, turns on, and the 12V control power supply for computer (PC) side, i.e., pMOS field effect transistor 127, turns on. When the input voltage, i.e., the voltage between terminals 201 and 202 in FIG. 2, further rises and exceeds the second constant voltage value, the 12V control PV side, i.e., pMOS field effect transistor 125, turns on, and the 12V control computer (PC) power supply side, i.e., pMOS field effect transistor 127, turns off. In the case of FIG. 12, a static margin is secured.

Looking at FIG. 13(b) and (c), when the input voltage, i.e., the voltage between terminals 201 and 202 in FIG. 2, is low, the 12V control PV side, i.e., pMOS field effect transistor 125, is off, and the 12V control computer (PC) power supply side, i.e., pMOS field effect transistor 127, is on. When the input voltage, i.e., the voltage between terminals 201 and 202 in FIG. 2, rises, the 12V control PV side, i.e., pMOS field effect transistor 125, is on, and the 12V control power supply for computer (PC) side, i.e., pMOS field effect transistor 127, is off. In the case of FIG. 13, a sufficient static margin is not ensured.

Looking at FIG. 14(b) and (c), when the input voltage, i.e., the voltage between terminals 201 and 202 in FIG. 2, is small, the 12V control PV side, i.e., pMOS field effect transistor 125, is off, and the 12V control power supply for computer (PC) side, i.e., pMOS field effect transistor 127, is on. When the input voltage, i.e., the voltage between terminals 201 and 202 in FIG. 2, rises, the 12V control PV side, i.e., pMOS field effect transistor 125, is on, and the 12V control power supply for computer (PC) side, i.e., pMOS field effect transistor 127, is off. In the case of FIG. 14, a sufficient static margin is not ensured.

Looking at FIG. 15(b) and (c), when the input voltage, i.e., the voltage between terminals 201 and 202 in FIG. 2, is small, the 12V control PV side, i.e., pMOS field effect transistor 125, is turned off, and the 12V control power supply for computer (PC) side, i.e., pMOS field effect transistor 127, is turned on. When the input voltage, i.e., the voltage between terminals 201 and 202 in FIG. 2, rises, the 12V control PV side, i.e., pMOS field effect transistor 125, is turned on, and the 12V control power supply for computer (PC) side, i.e., pMOS field effect transistor 127, is turned off. In the case of FIG. 15, a sufficient static margin is not ensured.

From FIG. 10 (circuit A), FIG. 11 (circuit I), FIG. 12 (circuit U), FIG. 13 (circuit E), FIG. 14 (circuit O), and FIG. 15 (circuit Ka), it can be said that if the first and second stages of amplification are provided separately and independently and the resistance values are adjusted, a static margin can be secured. In other words, from the viewpoint of securing a static margin, the first and second stages of amplification should be provided separately and independently, as in FIG. 10 (circuit A), FIG. 11 (circuit I), and FIG. 12 (circuit U).

Next, we will look at the dynamic margin. In FIGS. 10, 11, 12, 13, 14, and 15 (d) and (e), the vertical axis is the source-gate voltage of the pMOS field effect transistor 125 and the source-gate voltage of the pMOS field effect transistor 127. Therefore, in (d) and (e) of FIGS. 10, 11, 12, 13, 14, 15, and 16, when the voltage is large, the pMOS field effect transistor 125 and the pMOS field effect transistor 127 are turned on. A large dynamic margin means that the time during which both the pMOS field effect transistor 125 and the pMOS field effect transistor 127 are turned on is long. A sufficient dynamic margin means that the time during which both the pMOS field effect transistor 125 and the pMOS field effect transistor 127 are turned on is sufficient.

In (d) and (e) of FIGS. 10, 11, 12, 13, 14, and 15, the simulation is performed under the assumption that the input voltage (output voltage of solar module 11) is 0V from time 0 (seconds) to 0.05 (seconds), the input voltage (output voltage of solar module 11) is 19V from time 0.05 (seconds) to 0.10 (seconds), the input voltage (output voltage of solar module 11) is 0V from time 0.10 (seconds) to 0.15 (seconds), and the input voltage (output voltage of solar module 11) is 19V from time 0.15 (seconds) to 0.20 (seconds).

In the steady state, from time 0 (seconds) to 0.05 (seconds), the 12V control PV side, i.e., the pMOS field effect transistor 125, is off, and the 12V control power supply for computer (PC) side, i.e., the pMOS field effect transistor 127, is on. From time 0.05 (seconds) to 0.10 (seconds), the 12V control PV side, i.e., the pMOS field effect transistor 125, is on, and the 12V control power supply for computer (PC) side, i.e., the pMOS field effect transistor 127, is off, from 0.10 (seconds) to 0.15 (seconds), the 12V control PV side, i.e., pMOS field effect transistor 125 is off and the 12V control power supply for computer (PC) side, i.e., pMOS field effect transistor 127 is on, and from 0.15 (seconds) to 0.20 (seconds), the 12V control PV side, i.e., pMOS field effect transistor 125 is on and the 12V control power supply for computer (PC) side, i.e., pMOS field effect transistor 127 is off.

The differences between (d) and (e) in FIGS. 10, 11, 12, 13, 14, and 15 appear in the transient state.

Looking at FIG. 10(d) and (e), immediately after the input voltage (output voltage of solar module 11) changes from 0V to 19V, there is a state where the 12V control PV side, i.e., the pMOS field effect transistor 125 is on and the 12V control power supply for computer (PC) side, i.e., the pMOS field effect transistor 127 is on, and then the 12V control PV side, i.e., the pMOS field effect transistor 125 is on and the 12V control power supply for computer (PC) side, i.e., the pMOS field effect transistor 127 is off. Immediately after the input voltage (output voltage of solar module 11) changes from 19V to 0V, there is a state where the 12V control PV side, i.e., the pMOS field effect transistor 125 is on and the 12V control power supply for computer (PC) side, i.e., the pMOS field effect transistor 127 is on, and then the 12V control PV side, i.e., the pMOS field effect transistor 125 is off and the 12V control power supply for computer (PC) side, i.e., the pMOS field effect transistor 127 is on. In a transient state, there is a state in which both pMOS field effect transistors are on. When the voltage between the source and gate of the two pMOS field effect transistors is on at about 3V or more, as shown in FIG. 10(d)(e), there is a time of about 0.01 seconds (10 milliseconds) or more during which both pMOS field effect transistors are on. Therefore, it is considered that a sufficient dynamic margin is secured.

Looking at FIG. 11(d)(e), immediately after the input voltage (output voltage of the solar module 11) changes from 0V to 19V, there is no state in which the 12V control PV side, i.e., the pMOS field effect transistor 125, is on and the 12V control power supply for computer (PC) side, i.e., the pMOS field effect transistor 127, is on. Instead, the 12V control PV side, i.e., the pMOS field effect transistor 125, is on and the 12V control power supply for computer (PC) side, i.e., the pMOS field effect transistor 127, is off. Immediately after the input voltage (output voltage of the solar module 11) changes from 19V to 0V, there is no state in which the 12V control PV side, i.e., the pMOS field effect transistor 125 is on and the 12V control power supply for computer (PC) side, i.e., the pMOS field effect transistor 127 is on; instead, the 12V control PV side, i.e., the pMOS field effect transistor 125 is off and the 12V control power supply for computer (PC) side, i.e., the pMOS field effect transistor 127 is on. In the transient state, there is almost no state in which both pMOS field effect transistors are on. There is almost no time in which both pMOS field effect transistors are on. Therefore, it is considered that the dynamic margin is not sufficiently secured.

Looking at FIG. 12(d) and (e), immediately after the input voltage (output voltage of solar module 11) changes from 0V to 19V, there is a state where the 12V control PV side, i.e., the pMOS field effect transistor 125 is off and the 12V control power supply for computer (PC) side, i.e., the pMOS field effect transistor 127 is off, and then the 12V control PV side, i.e., the pMOS field effect transistor 125 is on and the 12V control power supply for computer (PC) side, i.e., the pMOS field effect transistor 127 is off. Immediately after the input voltage (output voltage of solar module 11) changes from 19V to 0V, there is a state where the 12V control PV side, i.e., the pMOS field effect transistor 125 is off and the 12V control power supply for computer (PC) side, i.e., the pMOS field effect transistor 127 is off, and then the 12V control PV side, i.e., the pMOS field effect transistor 125 is off and the 12V control power supply for computer (PC) side, i.e., the pMOS field effect transistor 127 is on. In the transient state, there is a state where both pMOS field effect transistors are off. When the voltage between the source and gate of the two pMOS field effect transistors is on at about 3V or more, there is a time of about 0.01 seconds (10 milliseconds) or more during which both pMOS field effect transistors are off, as shown in FIG. 12(d)(e). It is out of the question that both will be off, so it is considered that the dynamic margin is not sufficiently secured.

Looking at FIG. 13(d)(e), immediately after the input voltage (output voltage of the solar module 11) changes from 0V to 19V, there is a state where the 12V control PV side, i.e., the pMOS field effect transistor 125 is on and the 12V control power supply for computer (PC) side, i.e., the pMOS field effect transistor 127 is on, and then the 12V control PV side, i.e., the pMOS field effect transistor 125 is on and the 12V control power supply for computer (PC) side, i.e., the pMOS field effect transistor 127 is off. Immediately after the input voltage (output voltage of the solar module 511) changes from 19V to 0V, the 12V control PV side, i.e., the pMOS field effect transistor 125 is on, and the 12V control power supply for computer (PC) side, i.e., the pMOS field effect transistor 127 is on and then the 12V control PV side, i.e., the pMOS field effect transistor 125 is off, and the 12V control power supply for computer (PC) side, i.e., the pMOS field effect transistor 127 is on. In the transient state, there is a state in which both pMOS field effect transistors are on. When the voltage between the source and gate of the two pMOS field effect transistors is on at about 3V or more, there is a time of about 0.01 seconds (10 milliseconds) or more during which both pMOS field effect transistors are on, as shown in FIG. 13(d) and 13(e). Therefore, it is considered that the dynamic margin is sufficiently secured.

Looking at FIG. 14 (d) and (e), immediately after the input voltage (output voltage of solar module 11) changes from 0V to 19V, there is no state in which the 12V control PV side, i.e., pMOS field effect transistor 125 is on and the 12V control power supply for computer (PC) side, i.e., pMOS field effect transistor 127 is on. Instead, the 12V control PV side, i.e., pMOS field effect transistor 125 is on and the 12V control power supply for computer (PC) side, i.e., pMOS field effect transistor 127 is off. Immediately after the input voltage (output voltage of the solar module 511) changes from 19V to 0V, there is no state in which the 12V control PV side, i.e., the pMOS field effect transistor 125 is on and the 12V control power supply for computer (PC) side, i.e., the pMOS field effect transistor 127 is on; instead, the 12V control PV side, i.e., the pMOS field effect transistor 125 is off and the 12V control power supply for computer (PC) side, i.e., the pMOS field effect transistor 127 is on. In the transient state, there is almost no state in which both pMOS field effect transistors are on. There is almost no time in which both pMOS field effect transistors are on. Therefore, it is considered that the dynamic margin is not sufficiently secured.

Looking at FIG. 15(d) and (e), immediately after the input voltage (output voltage of solar module 11) changes from 0V to 19V, there is a state where the 12V control PV side, i.e., the pMOS field effect transistor 125 is off and the 12V control power supply for computer (PC) side, i.e., the pMOS field effect transistor 127 is off, and then the 12V control PV side, i.e., the pMOS field effect transistor 125 is on and the 12V control power supply for computer (PC) side, i.e., the pMOS field effect transistor 127 is off. Immediately after the input voltage (output voltage of solar module 11) changes from 19V to 0V, there is a state where the 12V control PV side, i.e., the pMOS field effect transistor 125 is off and the 12V control power supply for computer (PC) side, i.e., the pMOS field effect transistor 127 is off, and then the 12V control PV side, i.e., the pMOS field effect transistor 125 is off and the 12V control power supply for computer (PC) side, i.e., the pMOS field effect transistor 127 is on. In a transient state, there is a state in which both pMOS field effect transistors are off. When the voltage between the source and gate of the two pMOS field effect transistors is on at about 3V or more, as shown in FIG. 15(d) and 15(e), there is a time of about 0.01 seconds (10 milliseconds) or more during which both pMOS field effect transistors are off. Since it is out of the question that both are off, it is considered that the dynamic margin is not sufficiently secured.

From FIGS. 10, 11, 12, 13, 14, and 15, it can be said that if the last amplifying stage that directly drives the pMOS field effect transistor 125 and the pMOS field effect transistor 127 is nMOS inverter, a dynamic margin is secured. In the case of a CMOS inverter or a pMOS inverter, it can be said that the dynamic margin cannot be secured. The last stage, that is, the inverter that directly drives the pMOS field effect transistor 125 and the pMOS field effect transistor 127, should be an nMOS inverter.

Although no comparative experiment was conducted, we will explain why 108 is an nMOS inverter, 109 is a pMOS inverter, and 110 is a pMOS inverter in FIG. 2.

By doing this, when the pMOS field effect transistor 125 goes from off to on, the signal is transmitted at high speed by the field effect transistors in the nMOS inverter 108, pMOS inverter 109, and nMOS inverter 129, and the pMOS field effect transistor 125 goes from off to on quickly. On the other hand, when the pMOS field effect transistor 125 goes from on to off, the signal is transmitted slowly by the resistors in the nMOS inverter 108, pMOS inverter 109, and nMOS inverter 129, and the pMOS field effect transistor 125 goes from on to off slowly.

By doing this, when the pMOS field effect transistor 127 changes from off to on, the signal is transmitted at high speed by the field effect transistors in the pMOS inverter 110 and the nMOS inverter 130, and the pMOS field effect transistor 127 quickly changes from off to on. On the other hand, when the pMOS field effect transistor 127 changes from on to off, the signal is transmitted slowly by the resistors in the pMOS inverter 110 and the nMOS inverter 130, and the pMOS field effect transistor 127 slowly changes from on to off. By doing this, the pMOS field effect transistor 125 and the pMOS field effect transistor 127 change from off to on at high speed and from on to off slowly. Therefore, the dynamic margin can be maximized. However, if the final stages 129 and 130 are nMOS inverters, it is not considered to make much difference whether 108, 109, and 110 are nMOS inverters or pMOS inverters. Therefore, it is important for the final stages 129, 130, 149, and 150 to be nMOS inverters in order to ensure the dynamic margin.

From the above, it can be said that the circuit in FIG. 10 can ensure both static and dynamic margins and is the optimal of the six circuit configurations. In other words, the front stage is independent and separate, the resistance value of the resistive voltage divider circuit is optimized to ensure the static margin, and the final stage is an nMOS inverter to ensure the dynamic margin. In this way, stable operation can be achieved even if there are changes in the power generation status of various solar modules and changes in the consumption status of the power demand units of the computer (PC), such as the CPU 15, motherboard 16, storage 17, and GPU 18.

FIG. 16 is an explanatory diagram of cases where a reverse current prevention diode is necessary and not necessary. FIG. 16(a) is a diagram explaining that a reverse current prevention diode is not necessary in the case of a coordinated charging system with one solar module. The circuit 12 of the present invention is inserted between the solar module 11 and the power supply 13 for the computer (PC), but a reverse current prevention diode is not necessary between the solar module 11 and the circuit of the present invention 12 to flow current only in the direction from the solar module 11 to the circuit of the present invention.

In FIG. 2, when the solar module is not generating power, the voltage between terminals 201 and 202 becomes zero. When the computer (PC) is on, power is supplied to the power demand parts of the computer (PC), that is, the CPU 15, the motherboard 16, the storage 17, and the GPU, from the commercial power supply 14 and the power supply for computer (PC) 13. When the computer (PC) is off, only a constant power supply of 5V is supplied to the motherboard 16 from the commercial power supply 14 and the power supply for computer (PC) 13.

At this time, even if the potentials of the nodes 135 and 136 are about 12V, the pMOS field effect transistor 126 stops the reverse current, so that the current does not flow back from the node 135 through the pMOS field effect transistor 126, the pMOS field effect transistor 125, the DC-DC converter 122, and the terminal 201 to the solar module 11. Therefore, if there is only one solar module, a reverse current prevention diode is not necessary.

In other words, in the circuit of FIG. 2, when the output voltage of the solar module 11 is small, the connection between the solar module 11 and the node 135 is blocked, so a reverse current prevention diode is not necessary. Therefore, as in FIG. 16(a), a reverse current prevention diode is not necessary.

FIG. 16(b) is a diagram explaining the need for a reverse current prevention diode in the case of a coordinated charging system with two solar modules. When there are two solar modules as in FIG. 16(b), there are cases where one solar module is generating power and the other solar module is not generating power. In that case, if there is no reverse current prevention diode, current will flow from the solar module that is generating power to the solar module that is not generating power, and that amount of current will not be supplied to the power demand section. Therefore, when there are two solar modules, a reverse current prevention diode is necessary. Even in that case, in the circuit of FIG. 2, when the output voltage of the solar module 11 is small, the connection between the solar module 11 and the node 135 is blocked, so there is no reverse current flow from the node 135 to the solar module 11.

FIG. 16(c) is a diagram explaining why a reverse current prevention diode is necessary for an independent power supply system with one solar module. The independent power supply system is a system that stores the power of the solar module 11 in a lead storage battery 23 and supplies the power to the power demand section when necessary. For this reason, a storage battery such as a lead storage battery 23 is necessary. Without the reverse current prevention diode 21, when the solar module 11 is not generating power, a reverse current flows from the storage battery to the solar module 11, and the power stored in the storage battery flows out. For this reason, a reverse current prevention diode is necessary for an independent power supply system with one solar module.

FIG. 16(d) is a diagram explaining why a reverse current prevention diode is necessary for an independent power supply system with two solar modules. The independent power supply system is a system that stores the power of the solar module 11 in a lead storage battery 23 and supplies the power to the power demand section when necessary. For this reason, a storage battery such as a lead storage battery 23 is necessary. Without the reverse current prevention diode 21, when the solar module 11 is not generating power, a reverse current flows from the storage battery to the solar module 11, and the power stored in the storage battery is drained. In addition, without the reverse current prevention diode, a current flows from the solar module that is generating power to the solar module that is not generating power, and the corresponding current is not supplied to the power demand section. Therefore, a reverse current prevention diode is also necessary in an independent power supply system with two solar modules.

In conclusion, a cooperative power supply system with one solar module does not require the reverse current prevention diode that is required in many systems. A reverse current prevention diode has a forward effect voltage, and the voltage drops by about 0.4V to 1.0V. If a reverse current prevention diode is not required, there is no voltage drop, power loss can be prevented, and this contributes to improving the efficiency of the system.

FIG. 17 shows a circuit for interlocking the power supply with the computer (PC). What would happen if power continued to be supplied to terminals 206 and 210 even when the computer (PC) was turned off? In that case, the power supply fan would continue to run even when the computer (PC) was turned off. This would be of concern to many people. Not only that, but if power continues to be supplied to terminals 206 and 210 even after the computer (PC) is turned off, the computer (PC) may not turn on even if you try to turn it on afterwards. However, this may differ depending on the computer (PC). For this reason, when the computer (PC) is turned off, power should not be supplied to terminals 206 and 210.

To achieve this, when this circuit receives a signal to turn off the power supply of the computer (PC), it drops the node between resistors 105 and 106 to 0V, turns off pMOS field effect transistor 125 and pMOS field effect transistor 145, and prevents power from being supplied from solar module 11 to the power demanding parts of the computer (PC), namely CPU 15, motherboard 16, storage 17, and GPU 18. When a command to turn off the power supply of the computer (PC) arrives, H (high) is supplied to terminal 203, and this signal can be used.

When H (high) is supplied to terminal 203, after a certain period of time has passed, nMOS field effect transistor 104 turns on. Therefore, regardless of the voltage between terminals 201 and 202, the node between resistors 105 and 106 becomes almost the same as GND, that is, the voltage is close to 0V. As a result, the signal is inverted and amplified a total of three times by the nMOS inverter 108, the pMOS inverter 109, and the nMOS inverter 129, and H (high) is input to the pMOS field effect transistor 125 and the pMOS field effect transistor 126, which turn off the pMOS field effect transistor 125 and the pMOS field effect transistor 126. The signal is inverted and amplified a total of three times by the nMOS inverter 108, the pMOS inverter 109, and the nMOS inverter 149, and H (high) is input to the pMOS field effect transistor 145 and the pMOS field effect transistor 146, which turn off the pMOS field effect transistor 145 and the pMOS field effect transistor 146.

By the same token, the pMOS field effect transistor 127 and the pMOS field effect transistor 147 turn on. However, if the power supply for computer (PC) is off, no power is supplied from the power supply for computer (PC) 13. Since no power is supplied from the solar module 11, no power is supplied to the power demand parts of the computer (PC), namely the CPU 15, motherboard 16, storage 17, and GPU 18.

On the other hand, when L (low) is supplied to terminal 203, power is supplied from the power supply for computer (PC) 13, coordinated power supply from the solar module 11 or the power supply for computer (PC) 13, or power supply from the solar module 11 is performed according to the voltage between terminals 201 and 202, and power is supplied to the power demand parts, namely the CPU 15, motherboard 16, storage 17, and GPU 18.

Next, the delay circuit 102-1 will be described. The delay circuit 102-1 includes a resistor 102 and a capacitor 103, and operates with a CR time constant. For example, if the resistance of resistor 102 is 100 kΩ (kiloohms) and the capacitance of capacitor 103 is 47 μF (microfarads), the CR time constant is 4.7 seconds. When the power supply of the computer (PC) is turned off and the potential of terminal 203 becomes H (high), the voltage between resistors 105 and 106 becomes 0 V after 3 to 5 seconds, which is the same order of time as the CR time constant. When the power supply of the computer (PC) is turned on and the potential of terminal 203 becomes L (low), the voltage between resistors 105 and 106 becomes the potential due to the voltage divided between terminals 201 and 202 after 3 to 5 seconds, which is the same order of time as the CR time constant.

Let's consider the effect of using a delay circuit in this way. When a signal to turn off the power supply of the computer (PC) is received, the power supply from the power supply for computer (PC) 13 should be turned off. However, what would happen if the power from the solar module 11 were to stop before the power from the power supply for computer (PC) 13 was turned off? In this case, the power required by the power supply for computer (PC) 13 would suddenly increase, and from the viewpoint of the power supply for computer (PC) 13, a large amount of power was suddenly required, so it may decide that the power should not be turned off.

When a signal to turn on the computer (PC) is received, the power from the power supply for computer (PC) 13 should be turned on. However, what would happen if the power from the solar module 11 suddenly increased before the power from the power supply for computer (PC) 13 was turned on? In this case, the power required by the power supply for computer (PC) 13 would suddenly decrease, and from the viewpoint of the power supply for computer (PC) 13, power suddenly became unnecessary, so it may decide that it is not necessary to supply power, and stop supplying power. Although the power from the solar module 11 may be sufficient to cover all of the power for the 12V system, normal 5V system, the power supply for computer (PC) 13 must be prepared for a sudden increase in power demand and must be ready to supply power at any time.

FIG. 18 shows the pin assignment for the CPU power connector. FIG. 19 shows the pin assignment for the storage power connector. FIG. 20 shows the pin assignment for the motherboard power connector. FIG. 21 shows the pin assignment for the graphics board power connector.

FIG. 18, FIG. 19, FIG. 20, and FIG. 21 respectively show the specifications of the power connector of the part corresponding to the power demand part inside the computer (PC) and the connection in this system. The details of the connection have already been explained, so they will be omitted.

There are six types of power supplies: 12V, normal 5V, always-on 5V (5 VFSB), 3.3V, −5V, and −12V. In this embodiment, only 12V and normal 5V are used for coordinated power supply, and for always-on 5V (5 VFSB), 3.3V, −5V, and −12V, the input and output are simply connected. There is a degree of freedom in the design as to the extent to which coordinated power supply is used, so it is not necessarily necessary to use only 12V and normal 5V for coordinated power supply.

FIG. 22 shows an example of how to wire the power supply for computer (PC) side and the motherboard side in the power supply wiring of the motherboard. This example shows only the 12V part.

FIG. 22(a) is an example of how to wire between the power supply for computer (PC) side and the motherboard side in the power supply wiring of a normal computer (PC) motherboard. No. 10 on the power supply for computer (PC) side is connected to No. 10 on the motherboard side, and No. 11 on the power supply for computer (PC) side is connected to No. 11 on the motherboard side.

FIG. 22(b) is an example of how to wire between the power supply for computer (PC) side and the motherboard side in the computer (PC) of this invention. A switching element 127 is placed between “No. 10 and No. 11” on the power supply for computer (PC) side and “No. 10 and No. 11” on the motherboard side. In addition, the solar module 11 is connected to “No. 10 and No. 11” on the motherboard side via a DC-DC converter 122 and a switching element 125-1.

Numbers 10 and 11 on the power supply for computer (PC) side are connected to the circuit of the present invention at terminal 204. Numbers 10 and 11 on the motherboard side are connected to the circuit of the present invention at terminal 206. Solar module 11 is connected to the circuit of the present invention at terminal 201. Switching element 127 is connected to the outside of the circuit of the present invention at terminals 204 and 206. DC-DC converter 122 is connected to the outside of the circuit of the present invention at terminal 201. Switching element 125-1 is connected to the outside of the circuit of the present invention at terminal 206.

By appropriately controlling switching element 125-1 and switching element 127, the power from the power supply for computer (PC) and that from solar module 11 is mixed by coordinated power supply and supplied to numbers 10 and 11 on the motherboard side. This coordinated power supply uses the power from solar module 11 with priority, and supplies only the shortage from the power supply for computer (PC) side.

This embodiment assumes one solar module and one computer (PC). Such a small-scale system is suitable for generating electricity on the balcony of an ordinary home.

Now, the parts of the above description that are particularly patentable are summarized below.

1. Coordinated power supply is performed, and only the computer (PC) part is modified.

2. Static margin and dynamic margin are secured.

3. A delayed signal of the power control signal from the computer (PC) is used to control whether or not to supply power from the solar module.

The coordinated power supply in 1 is:
A technology that mixes power from the solar module and power from commercial AC,
It is based on feedback control,
It uses power from the solar module with priority, and uses power from commercial AC only when there is a shortage by the solar module.

This allows the power from the solar module to be used effectively when there is a demand for power, even without a storage battery. This eliminates the need for depreciation costs for the storage battery. In addition, the power from the solar module can be supplied to the power demand section of the computer (PC) without passing through 100V AC once using a power conditioner. The power from the solar module needs to be converted only once by the DC-DC converter, and the voltage difference in the conversion is small. This is advantageous in terms of efficiency, and the efficiency is improved. If the DC-DC converter is more efficient than the conversion efficiency from commercial AC 100V, it may be possible to save more power from commercial AC 100V than the power from the solar module. In addition, only the computer (PC) part needs to be modified, and there is no need to modify the power system of the entire house or building, so the threshold for introduction is low.

2. Ensuring a static margin and a dynamic margin is important for stable operation. The reason this invention has not been realized until now may be because there were problems with this stable operation. A static margin can be achieved by changing the judgment voltage of the first stage of amplification between the system from the solar module and the system from the PC power supply, and a dynamic margin can be achieved by making the final stage that directly drives the switching element an nMOS inverter.

3. By controlling whether to supply power from the solar module with a delayed signal of the power control signal from the computer (PC), it becomes possible to operate the power switch of the computer (PC), control the power supply from software, standby, and standby when there is no input for a certain period of time. This may have been an issue that prevented it from being realized until now.

This embodiment realizes a power system for computers that uses natural energy and can achieve high efficiency and stable operation. High efficiency is achieved by realizing power from the solar module once with a small voltage difference, extracting power at a voltage close to the voltage at which maximum power can be extracted, and not requiring a reverse current prevention diode. Stable operation is achieved by ensuring static and dynamic margins. In terms of a power supply system for computers, it is also possible to ensure compatibility with the power supply control of the computer. Also, since only the computer (PC) part needs to be modified, and there is no need to modify the power system of the entire house or building, the barrier to introduction is low.

### Second Embodiment

The second embodiment relates to a coordinated power supply system network. First, the circuit connections are explained, and then the features are explained. The second embodiment is an example in which two computers are connected to two solar modules. However, it is assumed that many computers are connected to many solar modules.

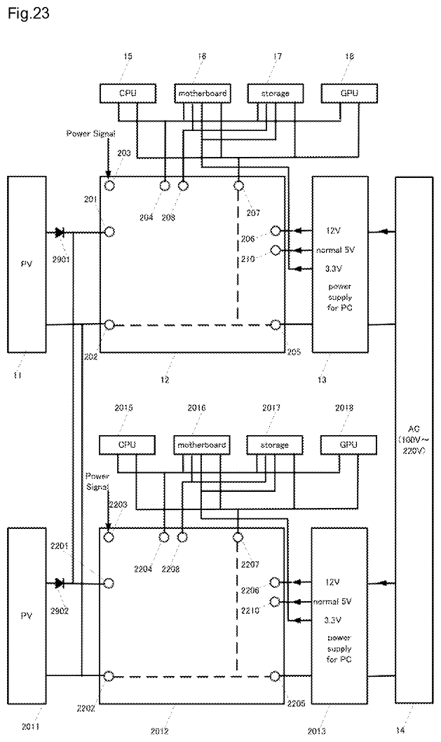

First, the circuit connections are explained. FIG. 23 is a block diagram of the first embodiment of the present invention. The DC power supply system of the first embodiment is composed of a solar module 11, a main circuit 12, a power supply for computer (PC) 13, a commercial power supply 14, a CPU 15, a motherboard 16, storage 17, a GPU 18, a reverse current prevention diode 2901, a solar module 2011, a main circuit 2012, a power supply for computer (PC) 2013, a commercial power supply 2014, a CPU 2015, a motherboard 2016, storage 2017, a GPU 2018, and a reverse current prevention diode 2902.

The positive side of the solar module 11 is connected to the reverse current prevention diode 2901. The negative side of the solar module 11 is connected to the main circuit 12 via the terminal 202.

The anode of the reverse current prevention diode 2901 is connected to the solar module 11. The cathode of the reverse current prevention diode 2901 is connected to the reverse current prevention diode 2902, the main circuit 12 via terminal 201, and to the main circuit 2012 via terminal 2201.

The positive side of the commercial power supply 14 is connected to the power supply for computer (PC) 13. The negative side of the commercial power supply 14 is connected to the power supply for computer (PC) 13. The normal 12V output of the power supply for computer (PC) is connected to the main circuit 12 via terminal 206. The normal 5V output of the power supply for computer (PC) is connected to the main circuit 12 via terminal 210. The normal 3.3V output of the power supply for computer (PC) is connected to the motherboard 16 and storage 17. The GND of the power supply for computer (PC) is connected to the main circuit 12 via terminal 205.

The normal 12V output of the main circuit 12 is connected to the CPU 15, motherboard 16, storage 17, and GPU 18 via terminal 204. The normal 5V output of the main circuit 12 is connected to the motherboard 16 and storage 17 via terminal 208. The GND of the main circuit 12 is connected to the CPU 15, motherboard 16, storage 17, and GPU 18 via terminal 207.

The second embodiment is an example in which two computers are connected to two solar modules. There are two computer (PC) power supplies, two main circuits, and two power demand units for the computers (PCs), and there are two solar modules. Reverse current prevention diodes 2901 and 2902 are connected to each solar module. These reverse current prevention diodes prevent current from flowing backward from one solar module through the other solar module.

The output of the two solar modules is shared to supply power to two main boards, power supplies for the computers (PCs), and power demand units. Compared to two systems in which one solar module supplies power to one main board, power supply for the computers (PCs), and power demand units, in a system in which the output of the two solar modules is shared and power is supplied to two main boards, power supplies for the computers (PCs), and power demand units, power can be shared, and the power utilization rate increases.

This system network is assumed to be connected to a large number of computers and a large number of solar modules. Therefore, the expected usage is a large number of solar modules, a main board, a power supply for a computer (PC), and a large number of power demand units, and even if the power generation status of each solar module is different or the power required by each power demand unit is different, it is relatively flexible. The first embodiment assumes one solar module and one computer (computer (PC)). Such a small-scale system is suitable for a system that generates power on the balcony of an ordinary home, but a system using many solar modules and many computers is suitable for an entire house, an office building, a commercial facility, a school, etc. The coordinated power supply system assumes that the generated power will be used immediately. Therefore, it is suitable for places where there is a daytime demand for power for computers. Since people are often in office buildings, commercial facilities, schools, etc. during the daytime, this system is suitable for installation in office buildings, commercial facilities, and schools during the day. In addition, the voltage of the solar module assumed is higher than that of the first embodiment, and 48V would be suitable.

Comparing the first and second embodiments, the main advantage of the second embodiment is that it allows power interchange, and the main disadvantage is that a reverse current prevention diode is required. With the second embodiment, in addition to the advantages of the first embodiment, a coordinated power supply system network that allows power interchange is realized.

The advantages over Patent Document 1 are as follows.
1. The outside of the part that corresponds individually to a PC (computer) is composed of commercial AC wiring and DC wiring from a solar module, which are common as of 2025, so the wiring when using commercial AC can be used as is. The only parts that change from the case where only commercial AC is used are mainly the parts that correspond individually to a PC (computer). The power supply for the PC (computer) can also be used as is. There is no need to completely replace the indoor wiring. In addition, since coordinated power supply is performed without using a storage battery, there is no depreciation cost for the storage battery.
2. Static and dynamic margins are secured to ensure stable operation of the PC (computer).
3. It provides a simple method of linking with the power button of a PC (computer) This specification describes the application of cooperative power supply and static and dynamic margins for stable operation to PCs (computers), achieving a high-quality power supply that operates reliably without batteries, among other benefits. However, this technology can also be used for applications requiring high-quality power supplies. For example, air conditioners require high-quality power supplies because their motors are vulnerable to power interruptions of a few tens of microseconds and because power is also supplied to electronic control circuits. Air conditioners convert standard commercial AC (100V in Japan) from AC to DC to AC to power the motor. DC from solar cells is mixed in at point \textcircled{2} to provide cooperative power supply. This ensures stable operation by ensuring static and dynamic margins, even without batteries. Assuming that the DC voltage of \textcircled{2} DC in an air conditioner's \textcircled{1}AC→\textcircled{2}DC→\textcircled{3}AC configuration is 240V, when combining power from solar cells in \textcircled{2}, the solar cell power can be boosted to 240V or stepped down to 240V, or it can be left unboosted or combined at approximately 240V or slightly higher voltages using linear control. By adjusting the \textcircled{2}DC→\textcircled{3}AC portion, it is possible to absorb minor voltage fluctuations in the \textcircled{2} DC portion. While there are design differences, such as the need to select high-voltage switching elements for 240V, the basic and essential concepts of this invention remain applicable. Thus, this invention is expected to have wide application in applications requiring high-quality power supplies, where stable operation achieved through DC power supply, coordinated power supply, and static and dynamic margins ensures stable operation without batteries.

### INDUSTRIAL APPLICABILITY

The system for one solar module and one computer given in the first embodiment is suitable for systems that generate electricity on the balcony of an ordinary home. The system using multiple solar modules and multiple computers given in the second embodiment is suitable for entire homes, office buildings, commercial facilities, schools, etc.

### EXPLANATION OF SYMBOLS

11 Solar module
12 Main circuit
13 Power supply for computer (PC)
14 Commercial AC
15 CPU
16 Motherboard
17 Storage
18 GPU
201, 202, 203, 204, 206, 207, 208, 210 Terminal
101, 121, 123, 131, 132, 133, 141, 143, 151, 152, 153 Capacitor
102, 105, 106, 107 Resistor
104 nMOS field effect transistor
108, 129, 130, 149, 150 nMOS inverter
109, 110 pMOS inverter
122 DC-DC converter (12V output)
142 DC-DC Converter (5V output)
125, 126, 127, 145, 146, 147 pMOS field effect transistor
124, 128, 144, 148 Diode
134, 135, 136, 154, 155, 156 Node
102-1 Delay circuit
106-1 Resistive voltage divider circuit
201 pMOS field effect transistor
202 Controller
203 Diode
204 Inductor
205, 206 Resistor
301, 302, 303, 304 Diode
305, 309 Capacitor
307 Transformer
312 Switching element
308 Controller
310 DC-DC converter (5V)
311 DC-DC converter (3.3V)
401, 404 Resistor
402 nMOS field effect transistor
403 pMOS field effect transistor
501, 502 Resistor
503 DC-DC converter
504, 505 Switching element
506, 507 Inverter
508 AC adapter
509 Commercial AC power source
510 Charging target (smartphone, etc.)
125-1 Switching element
1005, 1006, 1007, 1008-1, 1009-2, 1010-2, 1029-1, 1030-1, 1049-1, 1050-1 Resistors
1008-2, 1029-2, 1030-2, 1049-2, 1050-2 nMOS field effect transistors
1009-1, 1010-1 pMOS field effect transistors
1034, 1036, 1054, 1056 Capacitors
1035, 1037, 1055, 1057 Voltage measurement points
1105, 1106, 1107, 1108-1, 1109-2, 1110-2 Resistors
1108-2, 1129-2, 1130-2, 1149-2, 1150-2 nMOS field effect transistors
1109-1, 1110-1, 1129-1, 1130-1, 1149-1, 1150-1 pMOS field effect transistors
1134, 1136, 1154, 1156 Capacitors
1135, 1137, 1155, 1157 Voltage measurement points
1205, 1206, 1207, 1208-1, 1209-2, 1210-2, 1229-2, 1230-2, 1249-2, 1250-2 Resistors
1208-2 nMOS field effect transistors
1209-1, 1210-1, 1229-1, 1230-1, 1249-1, 1250-1 pMOS field effect transistors
1234, 1236, 1254, 1256 Capacitors
1235, 1237, 1255, 1257 Voltage measurement points
1305, 1307, 1308-1, 1309-1, 1329-1, 1330-2, 1349-1, 1350-1 Resistors
1308-2, 1309-2, 1329-2, 1330-2, 1349-2, 1350-2 nMOS field effect transistors
1334, 1336, 1354, 1356 Capacitors
1335, 1337, 1355, 1357 Voltage measurement points
1405, 1407, 1408-1, 1409-1 Resistors Resistor
1408-2, 1409-2, 1429-2, 1430-2, 1449-2, 1450-2 nMOS field effect transistor
1429-1, 1430-1, 1449-1, 1450-1 pMOS field effect transistor
1434, 1436, 1454, 1456 Capacitor
1435, 1437, 1455, 1457 Voltage measurement point
1505, 1507, 1508-1, 1509-1, 1529-2, 1530-2, 1549-2, 1550-2 Resistors
1508-2, 1509-2 nMOS field effect transistors
1529-1, 1530-1, 1549-1, 1550-1 pMOS field effect transistors
1534, 1536, 1554, 1556 Capacitors
1535, 1537, 1555, 1557 Voltage measurement points
11, 11-2 Solar modules
12 Circuit of the present invention (main circuit)
13 A power supply for computer (PC)
14 Commercial AC Power supply
21-1, 21-2 Reverse current prevention diode
22 General charge controller
23 Lead-acid battery
2011 Solar module
2012 Main circuit
2013 Power supply for computer (PC)
2015 CPU
2016 Motherboard
2017 Storage
2018 GPU
2201, 2202, 2203, 2204, 2206, 2207, 2208, 2210 Terminal
2901, 2902 Reverse current prevention diode

1. A power supply device comprising:
a first node, a second node, a third node, a fourth node;
a first DC-DC converter;
a first switching element or a group of first switching elements;
a second switching element or a group of second switching elements;
wherein the potential of the first node is output to the second node via the first DC-DC converter;
the first switching element or group thereof is connected between the second node and the fourth node;
the second switching element or group thereof is connected between the third node and the fourth node;
the first switching element or group thereof has a fully-off state, a fully-on state, and an intermediate state between on and off, and transitions analogously between on and off based on the voltage applied to its control terminal;
the second switching element or group thereof has a fully-off state, a fully-on state, and an intermediate state between on and off, and transitions analogously between on and off based on the voltage applied to its control terminal;
when the potential of the first node is equal to or less than a first predetermined potential value, the first switching element or group thereof is fully turned off, and the second switching element or group thereof is fully turned on;
when the potential of the first node is equal to or greater than a third predetermined potential value and equal to or less than a fourth predetermined potential value, both the first and second switching elements or groups thereof are fully turned on;
when the potential of the first node is equal to or greater than a second predetermined potential value, the first switching element or group thereof is fully turned on, and the second switching element or group thereof is fully turned off;
wherein the third predetermined potential value is greater than the first predetermined potential value, the fourth predetermined potential value is greater than the third predetermined potential value, and the second predetermined potential value is greater than the fourth predetermined potential value;
when the potential of the first node rapidly drops from a value exceeding the second predetermined potential value to a value below the first predetermined potential value, the first switching element or group thereof starts in an on state and the second switching element or group thereof starts in an off state, then both become on, and subsequently the first switching element or group thereof becomes off while the second switching element or group thereof remains on;
when the potential of the first node rapidly rises from a value below the first predetermined potential value to a value exceeding the second predetermined potential value, the first switching element or group thereof starts in an off state and the second switching element or group thereof starts in an on state, then both become on, and subsequently the first switching element or group thereof remains on while the second switching element or group thereof becomes off.

2. The power supply device according to claim 1, further comprising:
an eighth node, a ninth node, a first delay circuit, and a third switching element or a group of third switching elements;
wherein the eighth node is connected to the input of the first delay circuit;
the ninth node is connected to the output of the first delay circuit;
the ninth node is connected to the control terminal of the third switching element or group thereof;
and when the potential of the ninth node is within a specific potential range, the first switching element or group thereof is turned off, and the second switching element or group thereof is turned on.

3. The power supply device according to claim 2, wherein:
the eighth node is connected to the input of the first delay circuit;
when the state of the eighth node is at a first potential, the potential of a fifth node is determined by the first node;
when the state of the eighth node is at the first potential, the potential of a sixth node is determined by the first node;
when the state of the eighth node is at a second potential, the potential of the fifth node becomes a third potential;
when the state of the eighth node is at the second potential, the potential of the sixth node becomes the third potential;
when the state of the eighth node changes from the first potential to the second potential, after a first predetermined delay time, the potential of the fifth node changes from being determined by the first node to the third potential;
when the state of the eighth node changes from the first potential to the second potential, after a first predetermined delay time, the potential of the sixth node changes from being determined by the first node to the third potential;
when the state of the eighth node changes from the second potential to the first potential, after a first predetermined delay time, the potential of the fifth node changes from the third potential to being determined by the first node;
when the state of the eighth node changes from the second potential to the first potential, after a first predetermined delay time, the potential of the sixth node changes from the third potential to being determined by the first node.

4. The power supply device according to claim 3, wherein:
the first node is connected to a power generation device using natural energy;
the third node is connected to a node converted from an AC power source;
the fourth node is connected to a power demand section within a computer (PC);
and in the path from the natural energy power generation device through the first node, through the first DC-DC converter, through the second node, through the first switching element or group thereof, and to the fourth node, only one DC-to-DC voltage conversion is performed by the first DC-DC converter, and no other power conversion is performed;
and in the path where power is input via the third node converted from AC, only one AC-to-DC conversion is performed, and zero or one DC-to-DC conversion is performed.

5. The power supply device according to claim 4, wherein:
a signal that changes based on at least one of the following is connected to the eighth node:
a power button of a computer (PC),
a reset button of the computer (PC),
or information input into the operating system of the computer (PC).

6. The power supply device according to claim 5, wherein:
at least one capacitor is connected to the first node;
at least one capacitor is connected to the second node;
at least one capacitor is connected to the third node;
and at least one capacitor is connected to the fourth node.

7. The power supply device according to claim 6, wherein:
power from the fourth node is supplied to at least a motherboard and a storage device of the computer (PC).

8. A power supply device comprising:
a first node, a second node, a third node, a fourth node;
a first DC-DC converter;
a first switching element or a group of first switching elements;
a second switching element or a group of second switching elements;
wherein the potential of the first node is output to the second node via the first DC-DC converter;
the first switching element or group thereof is connected between the second node and the fourth node;
the second switching element or group thereof is connected between the third node and the fourth node;
the first switching element or group thereof has a fully-off state, a fully-on state, and an intermediate state between on and off, and transitions analogously between on and off based on the voltage applied to its control terminal;
the second switching element or group thereof has a fully-off state, a fully-on state, and an intermediate state between on and off;
further comprising a fifth node, a sixth node, a first amplifier circuit or group thereof, a second amplifier circuit or group thereof, a third amplifier circuit, a fourth amplifier circuit, and a resistive voltage divider;
wherein the first node is resistively divided by the resistive voltage divider and connected to the fifth node;
the first node is also resistively divided and connected to the sixth node;
the fifth node is amplified by the third amplifier circuit, optionally through zero or more amplification stages, and connected to the control terminal of the first switching element or group thereof;
the sixth node is amplified by the fourth amplifier circuit, through zero or more amplification stages, and connected to the control terminal of the second switching element or group thereof;
the third amplifier circuit includes an nMOS field-effect transistor and a resistor;
the fourth amplifier circuit includes an nMOS field-effect transistor and a resistor;
the fifth node and the sixth node are distinct nodes;
and the third and fourth amplifier circuits are distinct physical circuits.

9. The power supply device according to claim 8, further comprising:
an eighth node, a ninth node, a first delay circuit, and a third switching element or a group of third switching elements;
wherein the eighth node is connected to the input of the first delay circuit;
the ninth node is connected to the output of the first delay circuit;
and the ninth node is connected to the control terminal of the third switching element or group thereof.

10. The power supply device according to claim 9, wherein:
the first node is connected to a power generation device using natural energy;
the third node is connected to a node converted from an AC power source;
the fourth node is connected to a power demand section within a computer (PC);
and in the path from the natural energy power generation device through the first node, through the first DC-DC converter, through the second node, through the first switching element or group thereof, and to the fourth node, only one DC-to-DC voltage conversion device exists, performed solely by the first DC-DC converter, and no other power conversion is performed;
and in the path where power is input via the third node converted from AC, only one AC-to-DC conversion device exists, and zero or one DC-to-DC conversion device exists.

11. The power supply device according to claim 10, wherein:
at least one capacitor is connected to the first node;
at least one capacitor is connected to the second node;
at least one capacitor is connected to the third node;
and at least one capacitor is connected to the fourth node.

12. The power supply device according to claim 11, wherein:
the fourth node is directly or indirectly connected to at least a motherboard and a storage device of the computer (PC).
